(19) United States
(12) Patent Application Publication
(10) Pub. No.: US 2024/0244935 A1
(43) Pub. Date: Jul. 18, 2024

(54) DISPLAY DEVICE AND MANUFACTURING METHOD OF THE SAME

(71) Applicant: Samsung Display Co., LTD., Yongin-si (KR)

(72) Inventors: DOKYUNG YOUN, Yongin-si (KR); SANGJI PARK, Yongin-si (KR); CHEOL SHIN, Yongin-si (KR); KEUNCHAN OH, Yongin-si (KR); SONGEE LEE, Yongin-si (KR); SUN-KYU JOO, Yongin-si (KR); WOO-MAN JI, Yongin-si (KR); YOUYOUNG JIN, Yongin-si (KR); TAE HYUNG HWANG, Yongin-si (KR)

(21) Appl. No.: 18/385,924

(22) Filed: Nov. 1, 2023

(30) Foreign Application Priority Data
Jan. 13, 2023 (KR) 10-2023-0005107

(51) Int. Cl. H10K 59/80; H10K 59/12; H10K 59/122

(52) U.S. Cl. CPC H10K 59/879; H10K 59/1201; H10K 59/122

(57) ABSTRACT

A display device includes a display panel, a first light conversion layer, a second light conversion layer, and a light transmission layer, which are disposed on the display panel and spaced apart from each other, a plurality of bank layers, each of which is disposed on the display panel and which are disposed between the first light conversion layer and the second light conversion layer and between the light transmission layer and each of the first and second light conversion layers, a spacer, which is disposed below a bank layer of the bank layers and faces the display panel, and a plurality of lenses which are disposed below the first light conversion layer, the second light conversion layer, and the light transmission layer, and face the display panel. The spacer and the plurality of lenses may be disposed in a same layer.

This application claims priority to Korean Patent Application No. 10-2023-0005107, filed on Jan. 13, 2023, and all the benefits accruing therefrom under 35 U.S.C. § 119, the content of which in its entirety is herein incorporated by reference.

### BACKGROUND

### 1. Field

The disclosure herein relates to a display device and a manufacturing method of the same.

### 2. Description of the Related Art

Multimedia display devices such as televisions, mobile phones, tablet computers, computers, navigation units, and game consoles, may be provided with a display panel for displaying an image. The display panel may include a plurality of pixels for displaying the image, and each of the pixels may include a light-emitting element that generates light, and a driving element connected to the light-emitting element.

Recently, display devices, each of which includes light conversion layers and a light transmission layer in order to improve color purity, are developed. The light conversion layers and the light transmission layer are disposed on the pixels, and the light conversion layers convert light generated in the pixels into light having a different wavelength from that of the light generated in the pixels. The light generated in the pixels may pass through the light transmission layer. Each of the light conversion layers and the light transmission layer is disposed to overlap a corresponding pixel among the pixels. Each of the light conversion layers includes quantum dots and resin for converting a wavelength of the light. The light transmission layer includes a scatterer and resin.

### SUMMARY

The disclosure provides a display device with improved light efficiency and a manufacturing method of the display device.

An embodiment of the inventive concept provides a display device including a display panel, a first light conversion layer, a second light conversion layer, and a light transmission layer, which are disposed on the display panel and spaced apart from each other, a plurality of bank layers, each of which is disposed on the display panel and which are disposed between the first light conversion layer and the second light conversion layer and between the light transmission layer and each of the first and second light conversion layers, a spacer, which is disposed below a bank layer of the bank layers and faces the display panel, and a plurality of lenses which are disposed below the first light conversion layer, the second light conversion layer, and the light transmission layer, and face the display panel. The spacer and the plurality of lenses may be disposed in a same layer.

In an embodiment of the inventive concept, a display device manufacturing method includes forming a bank layer on a substrate, providing light conversion layers and a light transmission layer in openings defined in the bank layer, forming a spacer on the bank layer, forming a plurality of lenses on the light conversion layers and the light transmission layer, and disposing the light conversion layers and the light transmission layer on a display panel. The spacer and the plurality of lenses may be formed at a same time.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1 is a perspective view of an embodiment of a display device according to the inventive concept;

FIG. 2 is an exploded perspective view of the display device illustrated in FIG. 1;

FIG. 3 is a cross-sectional view of a display module illustrated in FIG. 2;

FIG. 4 is a plan view of a display panel illustrated in FIG. 2;

FIG. 5 is an enlarged plan view of a first region AA1 in FIG. 4;

FIG. 6 is a cross-sectional view taken along line I-I′ illustrated in FIG. 5;

FIG. 7 is an enlarged plan view of a light control layer disposed in the first region AA1 in FIG. 4;

FIGS. 8A and 8B are views of a display device according to Comparative Example;

FIGS. 9A and 9B are views of an embodiment of a display device according to the inventive concept;

FIGS. 10A and 10B are views for describing refraction of first light according to refractive index change in lenses;

FIGS. 11A and 11B illustrate another embodiment of lenses according to the inventive concept;

FIGS. 12A and 12B illustrate another embodiment of lenses according to the inventive concept; and

FIGS. 13A to 13F are views for describing a process for forming the light control layer illustrated in FIGS. 6 and 7.

### DETAILED DESCRIPTION

Advantages and features of the invention, and implementation methods thereof will be clarified through following embodiments described in detail with reference to the accompanying drawings. Embodiments of the disclosure may, however, be embodied in different forms and should not be construed as limited to the embodiments set forth herein. Rather, these embodiments are provided so that this disclosure will be thorough and complete, and will fully convey the scope of the invention to those skilled in the art. Further, the invention is only defined by scopes of claims. Like reference numerals refer to like elements throughout.

When an element or layer is also referred to as being “on” another element or layer, it may be directly on the other element or layer or a third element or layer may be interposed between the elements or layers. In contrast, when an element is also referred to as being “directly on” or “right on” another element, a third element or layer is not interposed between the elements. The term “and/or” includes any and all combinations of one or more of the associated listed items.

Spatially relative terms, such as “below”, “beneath”, “lower”, “above”, “upper”, may be used herein to easily describe a relationship between one element or component(s) and another element or component(s) as illustrated in the drawings. It will be understood that the spatially relative terms are intended to encompass different orientations of an element in use or operation in addition to the orientation shown in the drawings. Like reference numerals refer to like elements throughout.

It will be understood that, although the terms first, second, etc. may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the invention.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Additionally, the embodiments provided herein will be described with plan views and cross-sectional views as ideal schematic views of the invention. Accordingly, shapes of the exemplary views may be modified according to manufacturing techniques and/or allowable errors. Therefore, the embodiments of the invention are not limited to the predetermined shape illustrated in the exemplary views, but may include other shapes that may be created according to manufacturing processes. Thus, areas exemplified in the drawings have general properties, and are used to illustrate a predetermined shape of a region of an element. Thus, this should not be construed as limited to the scope of the invention.

Hereinafter, embodiments of the inventive concept will be described in more detail with reference to the accompanying drawings.

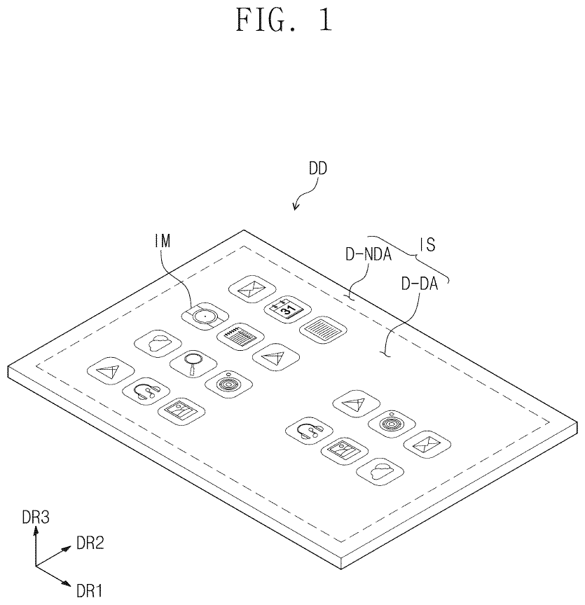

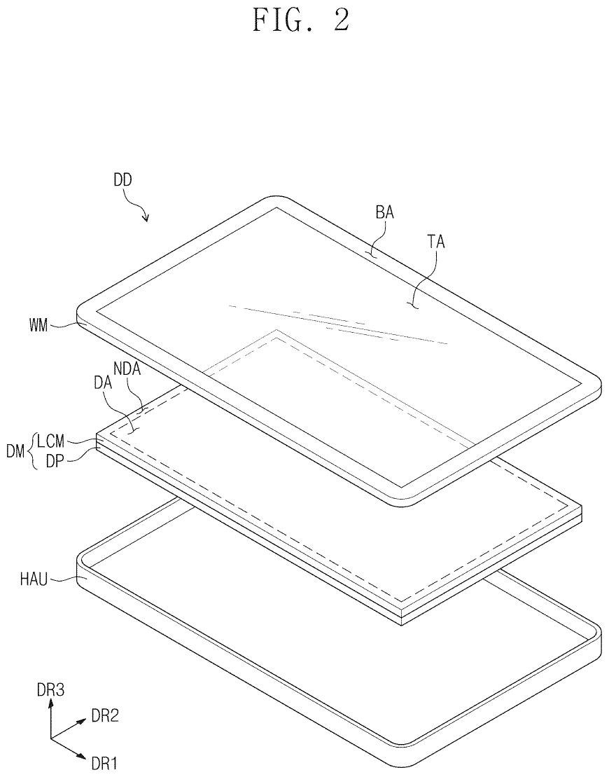

FIG. 1 is a perspective view of an embodiment of a display device according to the inventive concept. FIG. 2 is an exploded perspective view of the display device illustrated in FIG. 1.

Referring to FIG. 1, a display device DD may have a quadrangular shape, e.g., rectangular shape with long sides extending in a first direction DR1 and short sides extending in a second direction DR2 in a plan view. However, the inventive concept is not limited thereto, and the display device DD may have various shapes such as a circular shape or a polygonal shape.

Hereinafter, a third direction DR3 is defined as a direction substantially perpendicularly crossing a plane defined by the first direction DR1 and the second direction DR2. The state “in a plan view” used herein may mean a state as viewed in the third direction DR3.

The display device DD may include a top surface that is defined as a display surface IS, and may have a plane defined by the first direction DR1 and the second direction DR2. Images IM generated in the display device DD through the display surface IS may be provided for a user.

The display surface IS may include a display part D-DA and a non-display part D-NDA around the display part D-DA. The display part D-DA may display an image, and the non-display part D-NDA may not display an image. The non-display part D-NDA may surround the display part D-DA and define an edge of the display device DD, which is printed to have a predetermined color.

The display device DD may be used in large-sized electronic devices such as televisions, monitors, or outdoor billboards. In addition, the display device DD may be used in small and medium-sized electronic devices such as personal computers, notebook computers, personal digital assistants, vehicle navigation units, game consoles, smartphones, tablet computers, or cameras. However, these are just provided as examples, and the display device DD may be used in other electronic devices unless departing from the inventive concept.

Referring to FIG. 2, the display device DD may include a window WM, a display module DM, and an outer case HAU. The display module DM may include a display panel DP, and a light control member LCM disposed on the display panel DP.

The window WM and the outer case HAU may be coupled to each other to constitute an outer appearance of the display device DD, and may provide an inner space capable of accommodating components of the display device DD, such as the display module DM.

The window WM may be disposed on the display module DM. The window WM may protect the display module DM from external impact. The window WM may include a front surface that corresponds to the display surface IS (refer to FIG. 1) of the display device DD, which is described above. The front surface of the window WM may include a transmission region TA and a bezel region BA.

The transmission region TA of the window WM may be an optically transparent region. An image provided by the display module DM may be pass through the transmission region TA of the window WM, and the image may be visible to the user. The transmission region TA may correspond to the display part D-DA (refer to FIG. 1) of the display device DD.

The window WM may include an optically transparent insulating material. In an embodiment, the window WM may include glass, sapphire, plastic, or the like, for example. The window WM may have a single-layer structure or a multilayer structure. The window WM may further include a functional layer, such as an anti-fingerprint layer, a phase control layer or a hard coating layer, which is disposed on an optically transparent substrate.

The bezel region BA of the window WM may be a region provided by depositing, coating, or printing a material having a predetermined color on a transparent substrate. The bezel region BA of the window WM may prevent one component of the display module DM, which is disposed to overlap the bezel region BA, from being visible to the outside. The bezel region BA may correspond to the non-display part D-NDA (refer to FIG. 1) of the display device DD.

The display module DM may be disposed between the window WM and the outer case HAU. The display module DM may display an image in response to an electrical signal. The display module DM may include a display region DA and a non-display region NDA adjacent to the display region DA.

The display region DA may be a region that is activated in response to an electrical signal. The display region DA may be a region on which an image provided by the display panel DP is displayed. The display region DA of the display module DM may overlap at least a portion of the transmission region TA. The image output from the display region DA may be visible to the outside through the transmission region TA.

The non-display region NDA may be adjacent to the display region DA. In an embodiment, the non-display region NDA may surround the display region DA, for example. However, the inventive concept is not limited thereto, and the non-display region NDA may be defined to have various shapes. The non-display region NDA may be a region in which a driving circuit or driving wiring for driving elements disposed in the display region DA, various signal lines that provide the elements with electrical signals, and pads are disposed. The non-display region NDA may overlap at least a portion of the bezel region BA, and components of the display module DM, which are disposed in the non-display region NDA, may be prevented from being visible to the outside by the bezel region BA.

The display panel DP in an embodiment may be a light-emitting display panel, and is not particularly limited thereto. In an embodiment, the display panel DP may be an organic light-emitting display panel, an inorganic light-emitting display panel, or a quantum-dot light-emitting display panel, for example. An emission layer of the organic light-emitting display panel may include an organic luminescent material, and an emission layer of the inorganic light-emitting display panel may include an inorganic luminescent material. An emission layer of the quantum-dot light-emitting display panel may include a quantum dot and/or a quantum rod. Hereinafter, the display panel DP is described as the organic light-emitting display panel in this embodiment.

The light control member LCM may be disposed on the display panel DP. The light control member LCM may be manufactured through a separate process and then, provided on the display panel DP to be coupled to the display panel DP through a bonding process. However, the inventive concept is not limited thereto, and the light control member LCM may be formed on the display panel DP through a continuous process.

The light control member LCM may selectively transmit light provided by the display panel DP or selectively convert a wavelength of the light. In addition, the light control member LCM may prevent reflectance of external light incident from the outside of the display device DD.

The outer case HAU may be disposed below the display module DM and accommodate the display module DM. The outer case HAU may include a material having relatively high rigidity. The outer case HAU may absorb impact applied to the display module DM from the outside and prevent a foreign matter and/or moisture introduced into the display module DM, thereby protecting the display module DM. The outer case HAU in an embodiment may be provided in a shape in which a plurality of accommodation members is coupled thereto.

The display device DD may further include an input sensing module that obtains coordinate information of an external input applied from the outside of the display device DD. The input sensing module of the display device DD may be driven by various methods such as a capacitance method, a resistive method, an infrared method or a pressure method, and is not limited to any one.

In an embodiment, the input sensing module may be disposed on the display module DM. The input sensing module may be disposed directly on the display module DM through a continuous process. However, the disclosure is not limited thereto, and the input sensing module may be manufactured separately form the display panel DP and coupled onto the display panel DP through an adhesive layer. In an embodiment, the input sensing module may be disposed between components of the display module DM. In an embodiment, the input sensing module may be disposed between the display panel DP and the light control member LCM, for example.

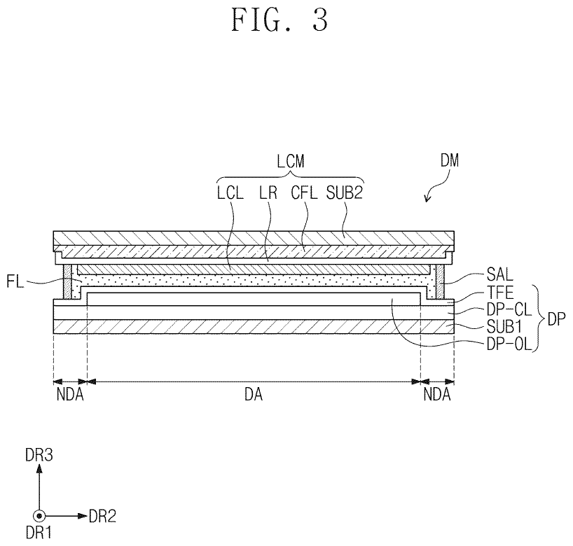

FIG. 3 is a cross-sectional view of a display module illustrated in FIG. 2.

A display panel DP and a light control member LCM in FIG. 3 are the same as/similar to the display panel DP and the light control member LCM, respectively, in FIG. 2 and thus, duplicate description will be omitted.

Referring to FIG. 3, a display module DM may include the display panel DP, the light control member LCM, and a sealing member SAL and a filling member FL that are disposed between the display panel DP and the light control member LCM.

The display panel DP may include a lower substrate SUB1, a circuit layer DP-CL, a display element layer DP-OL, and an encapsulation layer TFE.

The lower substrate SUB1 may include a glass substrate, a polymer substrate, or an organic/inorganic composite material substrate. The lower substrate SUB1 may include a top surface and a bottom surface, each of which is parallel to the first direction DR1 and the second direction DR2. The lower substrate SUB1 may include a display region DA and a non-display region NDA, and may provide a base surface on which components of the display panel DP are stacked. The circuit layer DP-CL, the display element layer DP-OL, and the encapsulation layer TFE may be sequentially stacked on the top surface of the lower substrate SUB1 in the third direction DR3.

The display element layer DP-OL may include light-emitting elements disposed in the display region DA. The circuit layer DP-CL may be disposed between the display element layer DP-OL and the lower substrate SUB1, and include driving elements connected to the light-emitting elements, signal lines, and pads. The light-emitting elements of the display element layer DP-OL may provide source light (or first light) toward the light control member LCM within the display region DA.

The encapsulation layer TFE may be disposed on the display element layer DP-OL and seal the light-emitting elements. The encapsulation layer TFE may include a plurality of thin films. The thin films of the encapsulation layer TFE may be disposed in order to improve optical efficiency of the light-emitting elements or protect the light-emitting elements.

The light control member LCM may include an upper substrate SUB2, a color filter layer CFL, a low refractive layer LR, and a light control layer LCL. The upper substrate SUB2 may include a front surface and a rear surface, each of which is parallel to the first direction DR1 and the second direction DR2. The rear surface of the upper substrate SUB2 may face the top surface of the lower substrate SUB1. The upper substrate SUB2 may provide a base surface on which components of the light control member LCM are stacked. The color filter layer CFL, the low refractive layer LR, and the light control layer LCL may be formed to be sequentially stacked on the rear surface of the upper substrate SUB2 in the third direction DR3.

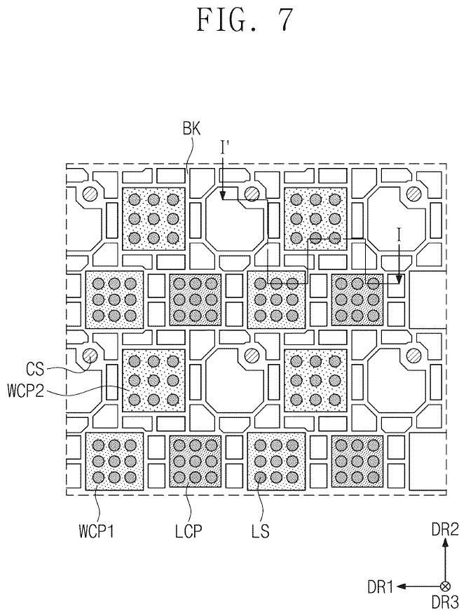

The light control layer LCL may include a light transmission layer and a light conversion layer that are disposed to overlap the display region DA. The light control layer LCL may extend from the display region DA and overlap the non-display region NDA. The light conversion layer of the light control layer LCL may convert a wavelength of the source light provided by the light-emitting elements. The source light may pass through the light transmission layer of the light control layer LCL. The light conversion layer and the light transmission layer will be described in detail with reference to FIG. 7.

The color filter layer CFL may be disposed to overlap the display region DA, and may filter the light passing through the light control layer LCL. The color filter layer CFL may include color filters that display the same color as that of the pixel. The color filter layer CFL may absorb light, which is not converted by and passes through the light control layer LCL, and prevent the color purity of the display device DD (refer to FIG. 1) from being decreased. In addition, the color filter layer CFL may filter external light such that the external light has the same colors as pixels, and reduce external light reflectance of the display device DD (refer to FIG. 1).

The color filter layer CFL may extend from the display region DA and overlap the non-display region NDA. The color filter layer CFL may include the color filters, which are disposed to overlap each other within the non-display region NDA, and absorb light that is emitted through or reflected by the non-display region NDA.

The sealing member SAL may be disposed between the display panel DP and the light control member LCM, and couple the display panel DP and the light control member LCM to each other. The sealing member SAL may overlap the non-display region NDA. The display panel DP and the light control member LCM may be formed through separate processes, respectively, and the display panel DP and the light control member LCM may be bonded using the sealing member SAL to manufacture the display module DM. The sealing member SAL may include an ultraviolet curable material, but the material of the sealing member SAL is not limited to the foregoing embodiment.

The filling member FL may be disposed between the display panel DP and the light control member LCM and fill an empty space between the display panel DP and the light control member LCM, which overlaps the display region DA. In an embodiment, the filling member FL may be disposed between the encapsulation layer TFE and the light control layer LCL. The filling member FL may include a silicon-based, epoxy-based or acrylic thermosetting material. However, the material of the filling member FL is not limited to the foregoing embodiments.

The light control member LCM may be disposed directly on the display panel DP in the display module DM. The light control member LCM may be formed on a top surface of the encapsulation layer TFE of the display panel DP through a continuous process. In this case, the sealing member SAL and the filling member FL may be omitted.

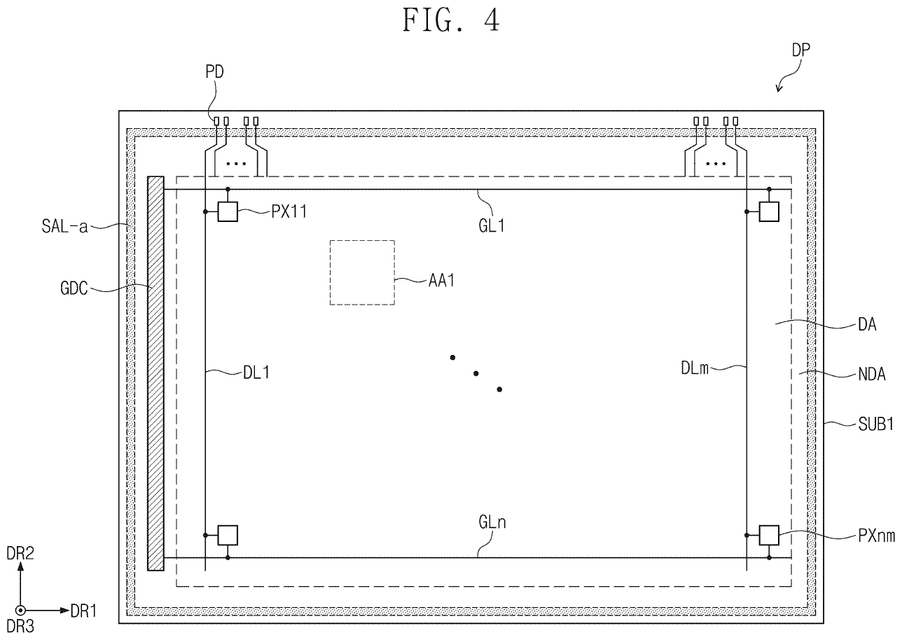

FIG. 4 is a plan view of the display panel illustrated in FIG. 2.

Referring to FIG. 4, a lower substrate SUB1 of the display panel DP may include a display region DA and a non-display region NDA. The display panel DP may include pixels PX11 to PXnm, signal lines GL1 to GLn and DL1 to DLm electrically connected to the pixels PX11 to PXnm, a driving circuit GDC, and pads PD. Here, n and m are natural numbers.

Each of the pixels PX11 to PXnm may include a pixel driving circuit constituted by a light-emitting element to be described later and a plurality of transistors (e.g., switching transistor, driving transistor, etc.) connected to the light-emitting element. The pixels PX11 to PXnm may emit light in response to an electrical signal applied to the pixels X11 to PXnm.

The pixels PX11 to PXnm may be disposed in the display region DA. However, the inventive concept is not limited thereto, and, in some of the pixels PX11 to PXnm, a transistor that constitutes the pixel may be disposed in the non-display region NDA. FIG. 4 illustrates the pixels PX11 to PXnm arranged in a matrix shape, but the arrangement shape of the pixels PX11 to PXnm is not limited thereto.

The signal lines GL1 to GLn and DL1 to DLm may include gate lines GL1 to GLn and data lines DL1 to DLm. Each of the pixels PX11 to PXnm may be connected to a corresponding gate line among the gate lines GL1 to GLn and a corresponding data line among the data lines DL1 to DLm. According to the configuration of the pixel driving circuit of the pixels PX11 to PXnm, more types of signal lines may be provided in the display panel DP.

The driving circuit GDC may be disposed in the non-display region NDA. However, the inventive concept is not limited thereto, and some of components of the driving circuit GDC may be disposed in the display region DA, thereby minimizing an area of the non-display region NDA. The driving circuit GDC may include a gate driving circuit. The gate driving circuit may generate gate signals and sequentially output the gate signals to the gate lines GL1 to GLn. The gate driving circuit may further output another control signal to the pixel driving circuit of the pixels PX11 to PXnm.

The pads PD may be disposed on the non-display region NDA in one direction. The pads PD may be portions that are connected to a circuit board. Each of the pads PD may be connected to a corresponding signal line among the plurality of signal lines GL1 to GLn and DL1 to DLm, and may be connected to a corresponding pixel through the signal line. The pads PD may have a shape integrated with the signal lines GL1 to GLn and DL1 to DLm. However, the inventive concept is not limited thereto, and the pads PD may be disposed in a layer different from a layer, on which the signal lines GL1 to GLn and DL1 to DLm are disposed, and be connected to the signal lines GL1 to GLn and DL1 to DLm through a contact hole.

FIG. 4 illustrates a sealing member arrangement region SAL-a corresponding to a region in which the sealing member SAL (refer to FIG. 3) is disposed in a plan view. The sealing member arrangement region SAL-a may correspond to a portion of the non-display region NDA. The sealing member arrangement region SAL-a may be adjacent to an edge of the display panel DP and extend in an extension direction of the edge. The sealing member arrangement region SAL-a may surround the display region DA in a plan view. In an embodiment, the sealing member arrangement region SAL-a may be disposed outward from a region in which the driving circuit GDC is disposed.

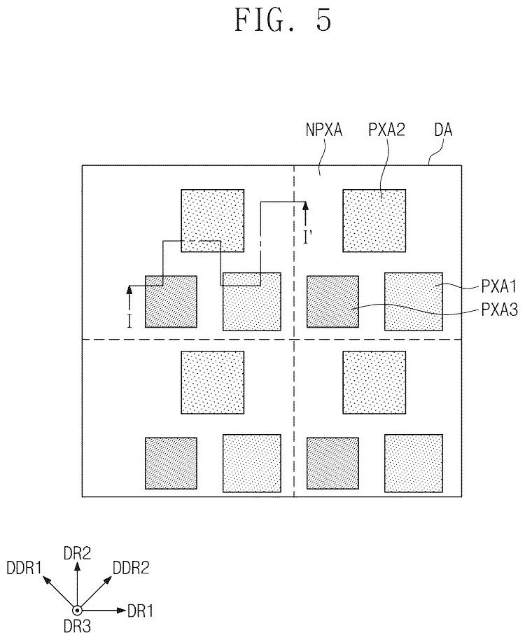

FIG. 5 is an enlarged plan view of first region AA1 in FIG. 4.

FIG. 5 illustrates an enlarged portion of the display region DA illustrated in FIG. 4.

Referring to FIG. 5, the display region DA may include emission regions PXA1, PXA2 and PXA3 that correspond to light-emitting elements, and a non-emission region NPXA that surrounds the emission regions PXA1, PXA2 and PXA3.

The emission regions PXA1, PXA2 and PXA3 may include first emission regions PXA1, second emission regions PXA2, and third emission regions PXA3. Hereinafter, one first emission region PXA1, one second emission region PXA2, and one third emission region PXA3 of the first emission regions PXA1, the second emission regions PXA2, and the third emission regions PXA3, respectively, will be described. The first emission region PXA1 may emit red light, the second emission region PXA2 may emit green light, and the third emission region PXA3 may emit blue light.

In an embodiment, the first emission region PXA1 and the third emission region PXA3 may be arranged in the first direction DR1. In an embodiment, the first emission region PXA1 and the second emission region PXA2 may be arranged in a first diagonal direction DDR1. In an embodiment, the second emission region PXA2 and the third emission region PXA3 may be arranged in a second diagonal direction DDR2. The first diagonal direction DDR1 may be defined as a direction crossing the first direction DR1 and the second direction DR2 in a plan view defined by the first and second directions DR1 and DR2. The second diagonal direction DDR2 may be defined as a direction crossing the first diagonal direction DDR1. However, the arrangement shape of the first to third emission regions PXA1, PXA2 and PXA3 is not limited thereto, and the first to third emission regions PXA1, PXA2 and PXA3 may be arranged in various shapes.

In an embodiment, each of the first to third emission regions PXA1, PXA2 and PXA3 may have a quadrangular shape, e.g., rectangular shape when viewed in a plan view, for example. However, the inventive concept is not limited thereto, and the first to third emission regions PXA1, PXA2 and PXA3 may have different shapes.

In an embodiment, the second emission region PXA2 may have an area that is larger than an area of each of the first and third emission regions PXA1 and PXA3 when viewed in a plan view, for example. The area of the first emission region PXA1 may be larger than the area of the third emission region PXA3 when viewed in a plan view. That is, the area of the second emission region PXA2 may be largest, and the area of the third emission region PXA3 may be smallest.

The embodiment illustrated in FIG. 5 is an example, and the shape, area, and arrangement shape of the first to third emission regions PXA1, PXA2 and PXA3 may change according to light-emitting efficiency of light.

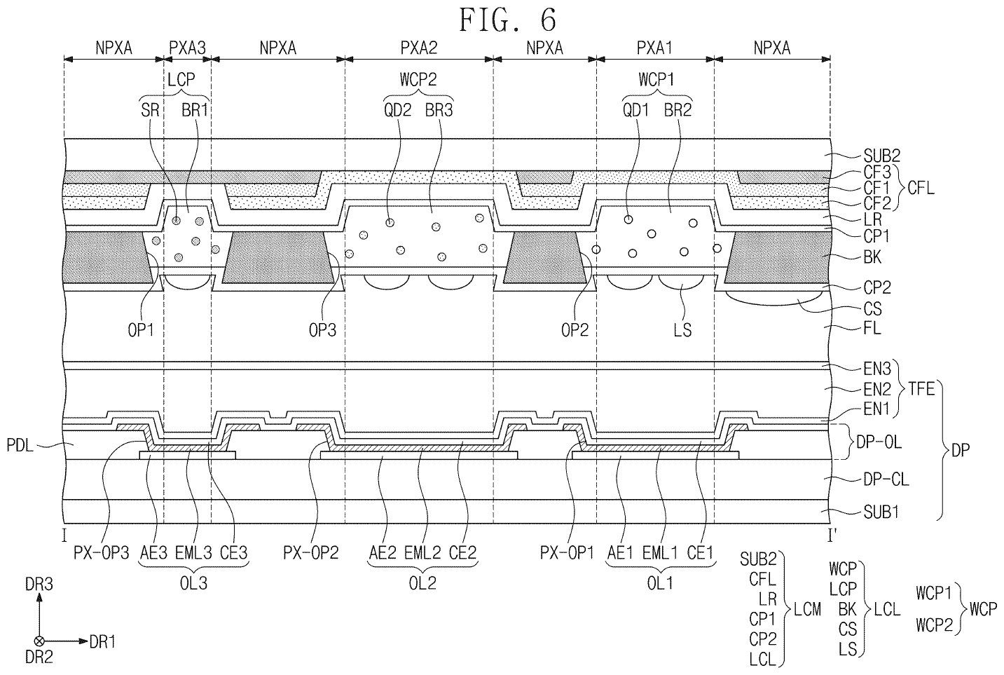

FIG. 6 is a cross-sectional view taken along line I-I′ illustrated in FIG. 5. FIG. 7 is an enlarged plan view of a light control layer disposed in the first region AA1 in FIG. 4.

FIG. 7 illustrates a plan view of the display module DM illustrated in FIG. 5 when viewed in a direction opposite to the third direction DR3.

In an embodiment, line I-I′ in FIG. 5 is symmetrically illustrated in FIG. 7.

A lower substrate SUB1, a circuit layer DP-CL, a display element layer DP-OL, an encapsulation layer TFE, a filling member FL, and a light control member LCM in FIG. 6 are the same as/similar to the lower substrate SUB1, the circuit layer DP-CL, the display element layer DP-OL, the encapsulation layer TFE, the filling member FL, and the light control member LCM, respectively, in FIG. 3 and thus, duplicate description will be omitted.

Referring to FIGS. 6 and 7, the display panel DP may include the lower substrate SUB1, the circuit layer DP-CL, the display element layer DP-OL, and the encapsulation layer TFE.

Although not illustrated, the display panel DP may include an insulation layer, a semiconductor pattern, a conductive pattern, a signal line, or the like. During manufacturing of the display panel DP, the insulation layer, a semiconductor layer, and a conductive layer may be formed on the lower substrate SUB1 through coating, deposition or the like, and then, the insulation layer, the semiconductor layer, and the conductive layer may be selectively patterned by performing a photolithography process. The semiconductor pattern, the conductive pattern, and the signal line, or the like, which are included in the display panel DP, may be formed through those processes.

The lower substrate SUB1 may provide a base surface on which the circuit layer DP-CL is formed. The lower substrate SUB1 may have a single-layer structure or have a multilayer structure. In an embodiment, the lower substrate SUB1 having a multilayer structure may include synthetic resin layers and at least one inorganic layer disposed between the synthetic resin layers, or include a glass substrate and a synthetic resin layer disposed on the glass substrate, for example. However, the embodiment of the lower substrate SUB1 is not limited thereto.

The synthetic resin layer included in the lower substrate SUB1 may include at least one of an acrylic resin, a methacrylic resin, polyisoprene, a vinyl-based resin, an epoxy-based resin, a urethane-based resin, a cellulose-based resin, a siloxane-based resin, a polyamide-based resin, a perylene-based resin, or a polyimide-based resin. However, the material of the synthetic resin layer is not limited to the foregoing embodiments.

Although not illustrated, the circuit layer DP-CL may include driving elements that constitute an equivalent circuit of pixels. In an embodiment, the circuit layer DP-CL may include at least one insulation layer, transistors connected to light-emitting elements OL1, OL2 and OL3, at least one capacitor, signal lines, or the like, for example. The transistors may be provided in plural. The plurality of transistors and the capacitor be connected to each other. Each of the transistors may include a semiconductor pattern, and the semiconductor pattern may be arranged in a predetermined rule according to a configuration of the equivalent circuit of the pixels in a plan view. The semiconductor pattern may include polysilicon, amorphous silicon, a crystalline oxide, or a non-crystalline oxide.

The display element layer DP-OL may be disposed on the circuit layer DP-CL. The display element layer DP-OL may include the first to third emission regions PXA1, PXA2 and PXA3 and the non-emission region NPXA, which are described above. The display element layer DP-OL may include a plurality of light-emitting elements OL1, OL2 and OL3 and a pixel defining film PDL.

The light-emitting elements OL1, OL2 and OL3 may include first to third light-emitting elements OL1, OL2 and OL3 that correspond to the first to third emission regions PXA1, PXA2 and PXA3, respectively. The first to third light-emitting elements OL1, OL2 and OL3 may include first electrodes AE1, AE2 and AE3, emission layers EML1, EML2 and EML3, and second electrodes CE1, CE2 and CE3, respectively.

The respective first electrodes AE1, AE2 and AE3 of the first to third light-emitting elements OL1, OL2 and OL3 may be spaced apart from each other on the circuit layer DP-CL. Although not illustrated, each of the respective first electrodes AE1, AE2 and AE3 of the first to third light-emitting elements OL1, OL2 and OL3 may be connected to a corresponding transistor of the circuit layer DP-CL. Each of the first electrodes AE1, AE2 and AE3 may be connected to other transistors and at least one capacitor by the transistor directly connected thereto.

The pixel defining film PDL may be disposed on the circuit layer DP-CL. In an embodiment, the pixel defining film PDL may be disposed on the uppermost insulation layer of the circuit layer DP-CL. Emission openings PX-OP1, PX-OP2 and PX-OP3, which expose at least portions of the first electrodes AE1, AE2 and AE3 of the light-emitting elements OL1, OL2 and OL3, respectively, may be defined in the pixel defining film PDL. Regions of the first electrodes AE1, AE2 and AE3 of the first to third light-emitting elements OL1, OL2 and OL3, which are exposed by the emission openings PX-OP1, PX-OP2 and PX-OP3 may correspond to the first to third emission regions PXA1, PXA2 and PXA3, respectively. The pixel defining film PDL may correspond to the non-emission region NPXA that surrounds the first to third emission regions PXA1, PXA2 and PXA3.

The emission openings PX-OP1, PX-OP2 and PX-OP3 may include a first emission opening PX-OP1, a second emission opening PX-OP2, and a third emission opening PX-OP3. The third emission opening PX-OP3 may have a length in the first direction DR1, which is smaller than a length of each of the first and second emission openings PX-OP1 and PX-OP2 in the first direction DR1. The length of the first emission opening PX-OP1 in the first direction DR1 may be smaller than the length of the second emission opening PX-OP2 in the first direction DR1.

The pixel defining film PDL may include a polymer resin. In an embodiment, the pixel defining film PDL may include a polyacrylate-based resin and a polyimide-based resin, for example. The pixel defining film PDL may further include an inorganic matter in addition to the polymer resin. However, the inventive concept is not limited thereto, and the pixel defining film PDL may include or consist of an inorganic matter. In an embodiment, the pixel defining film PDL may include a silicon nitride (SiNx), a silicon oxide (SiOx), a silicon oxynitride (SiOxNy), or the like, for example.

In an embodiment, the pixel defining film PDL may further include a light absorbing material. In an embodiment, the pixel defining film PDL may include a black coloring agent, for example. The black coloring agent may include a black pigment or a black dye. The black coloring agent may include a carbon black, a metal such as chrome, or an oxide thereof. However, the embodiment of the pixel defining film PDL is not limited thereto.

The emission layers EML1, EML2 and EML3 of the first to third light-emitting elements OL1, OL2 and OL3 may be disposed on the first electrodes AE1, AE2 and AE3, respectively. The emission layers EML1, EML2 and EML3 of the first to third light-emitting elements OL1, OL2 and OL3 may be disposed to correspond to the emission openings PX-OP1, PX-OP2 and PX-OP3, respectively. However, the disclosure is not limited thereto, and the respective emission layers EML1, EML2 and EML3 of the first to third light-emitting elements OL1, OL2 and OL3 may be provided as a common layer having a shape of one body.

Each of the emission layers EML1, EML2 and EML3 may include an organic luminescent material, an inorganic luminescent material, a quantum dot, a quantum rod, or the like. Each of the respective emission layers EML1, EML2 and EML3 of the first to third light-emitting elements OL1, OL2 and OL3 may generate source light. Here, the source light may be first light. In an embodiment, the first light may be blue light, for example, but an embodiment is not necessarily limited thereto. The respective emission layers EML1, EML2 and EML3 of the first to third light-emitting elements OL1, OL2 and OL3 may include the same configuration or have the same thickness. However, the inventive concept is not limited thereto, and the configurations and/or the thicknesses of the respective emission layers EML1, EML2 and EML3 of the first to third light-emitting elements OL1, OL2 and OL3 may be different from each other.

In an embodiment, the third emission layer EML3 exposed to the outside may have a width in the first direction DR1, which is smaller than a width of each of the first and second emission layers EML1 and EML2 exposed to the outside in the first direction DR1, for example. In an embodiment, the width of the first emission layer EML1 exposed to the outside in the first direction DR1 may be smaller than the width of the second emission layer EML2 exposed to the outside in the first direction DR1, for example.

Each of the first to third light-emitting elements OL1, OL2 and OL3 may be a light-emitting element having a tandem structure in which each of the emission layers EML1, EML2 and EML3 is provided in plural. The emission layers that are included in the first to third light-emitting elements OL1, OL2 and OL3, respectively, may be layers that generate light having substantially the same color. However, the inventive concept is not limited thereto, and some of the emission layers may generate light having a different color. In an embodiment, each of the light-emitting elements OL1, OL2 and OL3 may include four emission layers, and all of the four emission layers may generate substantially blue light, for example. However, the inventive concept is not limited thereto, and three of the four emission layers may generate blue light, and one emission layer may generate green light. Each of the light-emitting elements OL1, OL2 and OL3 having the tandem structure may further include a functional layer, such as a hole control layer, an electron control layer or a charge generation layer, which is disclosed between the emission layers.

The second electrodes CE1, CE2 and CE3 of the first to third light-emitting elements OL1, OL2 and OL3 may be disposed on the emission layers EML1, EML2 and EML3, respectively. The respective second electrodes CE1, CE2 and CE3 of the first to third light-emitting elements OL1, OL2 and OL3 may be provided as a common layer to have a shape of one body. The second electrode CE1, CE2 or CE3 may overlap the emission region PXA1, PXA2 or PXA3 and the non-emission region NPXA. A common voltage may be supplied to the pixels through the second electrodes CE1, CE2 and CE3.

A first voltage may be applied to the first electrodes AE1, AE2 and AE3, and a second voltage having a different level from that of the first voltage may be applied to the second electrodes CE1, CE2 and CE3. A hole and an electron injected into the emission layers EML1, EML2 and EML3 may be combined with each other to generate an exciton, and the light-emitting elements OL1, OL2 and OL3 may emit light while the exciton is transited to a ground state.

The light-emitting elements OL1, OL2 and OL3 may further include light-emitting functional layers, such as hole control layers or electron control layers, which are disclosed between the first electrodes AE1, AE2 and AE3 and the second electrodes CE1, CE2 and CE3, respectively. The hole control layer may be disposed between the first electrode and the emission layer and include at least one of a hole transport layer or a hole injection layer, and the electron control layer may be disposed between the emission layer and the second electrode and include at least one of an electron transport layer or an electron injection layer. The respective light-emitting functional layers of the light-emitting elements OL1, OL2 and OL3 may be provided as a common layer, and may overlap the emission region PXA1, PXA2 or PXA3, and the non-emission region NPXA.

The encapsulation layer TFE may be disposed on the display element layer DP-OL and seal the light-emitting elements OL1, OL2 and OL3. The encapsulation layer TFE may include first to third encapsulation films EN1, EN2 and EN3. The first encapsulation film EN1 may be disposed on the second electrodes CE1, CE2 and CE3, and the second encapsulation film EN2 and the third encapsulation film EN3 may be disposed in sequence on the first encapsulation film EN1.

In an embodiment, each of the first and third encapsulation films EN1 and EN3 may include an inorganic film, and the inorganic film may protect the display element layer DP-OL from moisture and/or oxygen. In an embodiment, the inorganic film may include at least one of aluminum oxide, titanium oxide, silicon oxide, silicon nitride, silicon oxynitride, zirconium oxide, or hafnium oxide, but is not limited to the foregoing embodiments, for example.

In an embodiment, the second encapsulation film EN2 may include an organic film, and the organic film may protect the display element layer DP-OL from a foreign matter such as dust particles. In an embodiment, the organic film may include an acrylic resin, but is not limited to the foregoing embodiment, for example.

The filling member FL may be disposed between the display panel DP and the light control member LCM. A gap space between the display panel DP and the light control member LCM may be filled with the filling member FL. However, the inventive concept is not limited thereto, and the filling member FL may be omitted and the light control member LCM may be disposed directly on the display panel DP.

The light control member LCM may be disposed on the filling member FL. The light control member LCM may be disposed on the display panel DP. The filling member FL may be disposed between the display panel DP and the light control member LCM.

The light control member LCM may include an upper substrate SUB2, a color filter layer CFL, a low refractive layer LR, a light control layer LCL, a first capping layer CP1, and a second capping layer CP2.

The color filter layer CFL, the low refractive layer LR, the first capping layer CP1, the light control layer LCL, and the second capping layer CP2 may be disposed in sequence on a rear surface of the upper substrate SUB2 in the third direction DR3. The rear surface of the upper substrate SUB2 may be defined as a surface that faces a top surface of the lower substrate SUB1.

The light control layer LCL may include light conversion layers WCP, a light transmission layer LCP, bank layers BK, spacers CS, and lenses LS. The bank layers BK may be disposed on a rear surface of the first capping layer CP1. The rear surface of the first capping layer CP1 may be defined as a surface that faces the display panel DP. The bank layers BK may overlap the non-emission region NPXA. The bank layers BK may be spaced apart from each other in the first direction DR1 when viewed in the second direction DR2, but the bank layers BK may be substantially formed as one body as illustrated in FIG. 7.

The bank layers BK may include a black pigment and water-repellent materials. As each of the bank layers BK includes the black pigment, the bank layer BK may have a black color. Thus, the bank layers BK may block light so that colors of light emitted from the light-emitting elements OL1, OL2 and OL3 are not mixed.

A plurality of openings OP1, OP2 and OP3 may be defined by the bank layers BK that are adjacent to each other in the first direction DR1.

The light transmission layer LCP may be disposed between the display panel DP and the low refractive layer LR. The light transmission layer LCP may be disposed on the rear surface of the first capping layer CP1. The rear surface of the first capping layer CP1 may be defined as a surface that faces the display panel DP. The light transmission layer LCP may be disposed in a first opening OP1 defined by the bank layers BK.

The light transmission layer LCP may overlap the third emission region PXA3 and the non-emission regions NPXA adjacent to the third emission region PXA3. The light transmission layer LCP may overlap the third light-emitting element OL3.

The light transmission layer LCP may include a first base resin BR1 and scatterers SR dispersed in the first base resin BR1. The scatterers SR may scatter light, which is incident on the light transmission layer LCP from the third light-emitting element OL3, in several directions. The scatterers SR may be particles having relatively high density or predetermined gravity. In an embodiment, the scatterers SR may include a titanium oxide (TiOx), a silica-based nanoparticle, or the like, for example. The scatterers SR may improve light-emitting efficiency of light provided from the light-emitting element and passing through the light transmission layer LCP.

First light provided from the third light-emitting element OL3 may pass through the light transmission layer LCP. In an embodiment, the third light-emitting element OL3 may provide the light transmission layer LCP with blue light, and the blue light may pass through the light transmission layer LCP and be emitted toward a front direction of the display module DM, for example.

The light conversion layers WCP may be disposed in the second and third openings OP2 and OP3, respectively. The light conversion layers WCP may be disposed between the first and second capping layers CP1 and CP2 to be described later. The light conversion layers WCP may be disposed between the low refractive layer LR and the display panel DP. The light conversion layers WCP and the light transmission layer LCP may be disposed in the same layer.

The light conversion layers WCP may overlap a first emission region PXA1 and a second emission region PXA2, respectively. The light conversion layers WCP may overlap the first light-emitting element OL1 and the second light-emitting element OL2, respectively.

The light conversion layers WCP may include a first light conversion layer WCP1 and a second light conversion layer WCP2. The first light conversion layer WCP1 may be disposed in the second opening OP2. The second light conversion layer WCP2 may be disposed in the third opening OP3. The first and second light conversion layers WCP1 and WCP2 and the light transmission layer LCP may be arranged in the first direction DR1 when viewed in the second direction DR2.

The first to third emission regions PXA1 to PXA3 may be surrounded by the bank layers BK when viewed in a plan view.

The first light conversion layer WCP1 may overlap the first emission region PXA1. The first light conversion layer WCP1 may overlap the first light-emitting element OL1. The second light conversion layer WCP2 may overlap the second emission region PXA2. The second light conversion layer WCP2 may overlap the second light-emitting element OL2.

The second light conversion layer WCP2 may have a width larger than a width of each of the first light conversion layer WCP1 and the light transmission layer LCP in the first direction DR1. The width of the first light conversion layer WCP1 may be larger than the width of the light transmission layer LCP in the first direction DR1. That is, the width of the second light conversion layer WCP2 may be largest, and the width of the light transmission layer LCP may be smallest when viewed in the second direction DR2.

The first light conversion layer WCP1 may include a second base resin BR2 and first quantum dots QD1 dispersed in the second base resin BR2. The second light conversion layer WCP2 may include the third base resin BR3 and second quantum dots QD2 dispersed in the third base resin BR3.

Each of the quantum dots QD1 and QD2, which are included in the first light conversion layer WCP1 and the second light conversion layer WCP2, respectively, may have a core that is selected from a Group II-VI compound, a Group III-VI compound, a Group I-III-VI compound, a Group III-V compound, a Group IV-VI compound, a Group IV element, a Group IV compound, and any combinations thereof.

The Group II-VI compound may be selected from the group including a binary compound selected from the group including CdSe, CdTe, CdS, ZnS, ZnSe, ZnTe, ZnO, HgS, HgSe, HgTe, MgSe, MgS, and any combinations thereof, a ternary compound selected from the group including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any combinations thereof, and a quaternary compound selected from the group including HgZnTeS, CdZnSeS, CdZnSeTe, CdZnSTe, CdHgSeS, CdHgSeTe, CdHgSTe, HgZnSeS, HgZnSeTe, HgZnSTe, and any combinations thereof.

The Group III-VI compound may include a binary compound such as In2S3 and In2Se3, a ternary compound such as InGaS3 and InGaSe3, or any combination thereof.

The Group I-III-VI compound may be selected from a ternary compound selected from the group including AgInS, AgInS₂, CuInS, CuInS₂, AgGaS₂, CuGaS₂, CuGaO₂, AgGaO₂, AgAlO₂, and any combinations thereof, or a quaternary compound such as AgInGaS₂ and CuInGaS₂.

The Group III-V compound may be selected from the group including a binary compound selected from the group including GaN, GaP, GaAs, GaSb, AlN, AIP, AlAs, AlSb, InN, InP, InAs, InSb, and any combinations thereof, a ternary compound selected from the group including GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and any combinations thereof, and a quaternary compound selected from the group including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any combinations thereof. The Group III-V compound may further include a Group II metal. In an embodiment, a Group III-II-V compound may be selected from InZnP or the like, for example.

The Group IV-VI compound may be selected from the group including a binary compound selected from the group including SnS, SnSe, SnTe, PbS, PbSe, PbTe, and any combinations thereof, a ternary compound selected from the group including SnSeS, SnSeTe, SnSTe, PbSeS, PbSeTe, PbSTe, SnPbS, SnPbSe, SnPbTe, and any combinations thereof, and a quaternary compound selected from the group including SnPbSSe, SnPbSeTe, SnPbSTe, and any combinations thereof. The Group IV element may be selected from the group including Si, Ge, and any combinations thereof. The Group IV compound may be a binary compound selected from the group including SiC, SiGe, and any combinations thereof.

Each of elements included in a multi-element compound such as the binary compound, the ternary compound and the quaternary compound, may be in a particle at a uniform concentration or non-uniform concentration. That is, each of the foregoing formulas may mean types of the elements included in the compound, and an element ratio in the compound may be different. In an embodiment, AgInGaS₂ may mean AgInₓGa₁₋ₓS₂ (x is a real number from about 1 to about 1).

Each of the quantum dots may have a single structure or a dual core-shell structure in which each of the elements included in the quantum dot has a uniform concentration. In an embodiment, a material included in the core and a material included in the shell may be different from each other, for example.

In an embodiment, each of the quantum dots QD1 and QD2 may have the core-shell structure having nanocrystals. The shell of the quantum dot may serve as a protective layer, which prevents chemical deformation of the core so as to maintain semiconductor properties, and/or a charging layer for imparting electrophoresis properties to the quantum dot. The shell may have a single-layer structure or a multilayer structure. An interface between the core and the shell may have a concentration gradient in which a concentration of an element in the shell gradually decreases toward a center. In embodiments, the shell of the quantum dot may include a metal oxide, a non-metal oxide, a semiconductor compound, or any combinations thereof.

In an embodiment, the metal oxide or non-metal oxide may include a binary compound such as SiO2, Al2O3, TiO2, ZnO, MnO, Mn2O3, Mn3O4, CuO, FeO, Fe2O3, Fe3O4, CoO, Co3O4, and NiO, or a ternary compound such as MgAl2O4, CoFe2O4, NiFe2O4, and CoMn2O4, for example. However, the material is not limited to the foregoing embodiments.

In addition, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb. However, the material is not limited to the foregoing embodiments.

Each of elements included in a multi-element compound such as the binary compound, the ternary compound and the quaternary compound, may be in a particle at a uniform concentration or non-uniform concentration. That is, each of the foregoing formulas may mean types of the elements included in the compound, and an element ratio in the compound may be different.

Each of the quantum dots QD1 and QD2 may have a full width of half maximum (“FWHM”) in an emission wavelength spectrum of about 45 nm or less, preferably about 40 nm or less, more preferably about 30 nm or less, and, in this range, the color purity or color reproducibility may be improved. In addition, as light emitted through such quantum dots QD1 and QD2 is emitted in all directions, a wide viewing angle may be improved.

The shape of the quantum dots QD1 and QD2 is one generally used in the relevant art and is not particularly limited. In an embodiment, the quantum dots may be used which are spherical, pyramidal, multi-armed, or in the form of a cubic nanoparticle, a nanotube, a nanowire, a nanofiber, a nanoplate particle, or the like, for example.

The quantum dots QD1 and QD2 may adjust a color of emitted light by adjusting a particle size or an element ratio in the compound and accordingly, the quantum dots QD1 and QD2 may have various emission colors such as blue, red, and green. Accordingly, the first quantum dots QD1 may convert first light, which is provided by the first light-emitting element OL1, into second light having a different wavelength from the first light. In an embodiment, the first quantum dots QD1 may convert the first light, which is provided by the first light-emitting element OL1, into red light, for example. Accordingly, the display module DM may emit the red light through the first emission region PXA1.

The second quantum dots QD2 may convert first light, which is provided by the second light-emitting element OL2, into third light having a different wavelength range from the first light. Here, the wavelength range of the second light and the wavelength range of the third light may be different from each other. In an embodiment, the second quantum dots QD2 may convert the first light, which is provided by the second light-emitting element OL2, into green light, for example. Accordingly, the display module DM may emit the green light through the second emission region PXA2.

The low refractive layer LR may be disposed between the light control layer LCL and the color filter layer CFL. The low refractive layer LR may have a refractive index that is lower than a refractive index of each of the first and second light conversion layers WCP1 and WCP2 and the light transmission layer LCP. In an embodiment, the refractive index of the low refractive layer LR may be about 1.1 to about 1.5, specifically about 1.1 to about 1.35, for example. However, the refractive index of the low refractive layer LR is not limited to the forgoing numerical value examples. The low refractive layer LR may include a low refractive organic film having a relatively low refractive index. The low refractive layer LR may further include hollow particles and/or voids dispersed in an organic film, and the refractive index of the low refractive layer LR may be adjusted by a ratio of the hollow particles and/or the voids.

Light, which is not converted by the light conversion layers WCP1 and WCP2 and is emitted from a top surface of each of the light conversion layers WCP1 and WCP2 may be incident on the inside of the light conversion layers WCP1 and WCP2 again by the refractive index of the low refractive layer LR disposed on the light control layer LCL. The light incident on the inside of the light conversion layers WCP1 and WCP2 again by the low refractive layer LR may be converted by the quantum dots QD1 and QD2. That is, the low refractive layer LR may improve the light-emitting efficiency of the display device DD (refer to FIG. 1) through light recycling using the refractive index.

The low refractive layer LR may include a material having a relatively high light transmittance. In an embodiment, the low refractive layer LR may have a relatively high transmittance of about 90% or higher, for example. As the low refractive layer LR has the relatively high transmittance, the transmittance of the light emitted toward the front surface of the display module DM may not be reduced.

The first capping layer CP1 may be disposed on the low refractive layer LR facing the display panel DP. The first capping layer CP1 may include an inorganic matter. The first capping layer CP1 may prevent moisture or gas from being introduced into the low refractive layer LR.

The second capping layer CP2 may be disposed on the light control layer LCL facing the display panel DP. The second capping layer CP2 may include an inorganic matter. The second capping layer CP2 may prevent moisture or foreign matters from being introduced into the light control layer LCL. The first capping layer CP1 and the second capping layer CP2 may cover an upper portion and a lower portion, respectively, of the light control layer LCL, thereby protecting the light control layer LCL and preventing degradation caused by moisture.

The spacer CS may be disposed below the second capping layer CP2. The spacer CS may be disposed below a bottom surface of one bank layer BK of the bank layers BK. The bottom surface of the bank layer BK may be a surface facing the display panel DP. The spacer CS may face the display panel DP. Although the spacer CS is disposed below the bank layer BK adjacent to the first light conversion layer WCP1 in an embodiment, the inventive concept is not limited thereto and the position of the spacer CS may change.

The spacer CS may have a curve that is downwardly convex toward the display panel DP when viewed in the second direction DR2.

The spacer CS may maintain spacing between the display panel DP and the light control member LCM. In an embodiment, the spacer CS may serve to maintain a cell gap (or spacing) between the display panel DP and the light control member LCM, for example.

The spacer CS may have a refractive index that is different from a refractive index of each of the filling member FL and the second capping layer CP2. Specifically, the refractive index of the spacer CS may be higher than the refractive index each of the filling member FL and the second capping layer CP2.

A plurality of lenses LS may be disposed below bottom surfaces of the first light conversion layer WCP1, the second light conversion layer WCP2, and the light transmission layer LCP, respectively. The lenses LS may be disposed below the second capping layer CP2. The lenses LS may be disposed between the second capping layer CP2 and the filling member FL. The lenses LS may face the display panel DP. The bottom surface of each of the first light conversion layer WCP1, the second light conversion layer WCP2, and the light transmission layer LCP may be defined as a surface facing the display panel DP.

The lenses LS may be disposed in the same layer as the spacer CS. The spacer CS may be more adjacent to the display panel DP than the lenses LS are. The lenses LS may be more adjacent to the color filter layer CFL than the spacer CS is.

As illustrated in FIG. 7, the lenses LS may be arranged in a matrix shape on the bottom surfaces of the first light conversion layer WCP1, the second light conversion layer WCP2, and the light transmission layer LCP, respectively, when viewed in a plan view. Although nine lenses LS are disposed on the bottom surface of each of the first light conversion layer WCP1, the second light conversion layer WCP2, and the light transmission layer LCP in an embodiment, the inventive concept is not limited thereto, and the number of the lenses LS may change according to the size of the lenses LS and the size of each of the first light conversion layer WCP1, the second light conversion layer WCP2, and the light transmission layer LCP.

Each of the lenses LS may include a curve that is convex toward the display panel DP when viewed in the second direction DR2. Each of the lenses LS may have a circular shape when viewed in a plan view.

The lenses LS may have a refractive index that is different from the refractive index of each of the filling member FL and the second capping layer CP2. Specifically, the refractive index of the lenses LS may be higher than the refractive index of each of the filling member FL and the second capping layer CP2.

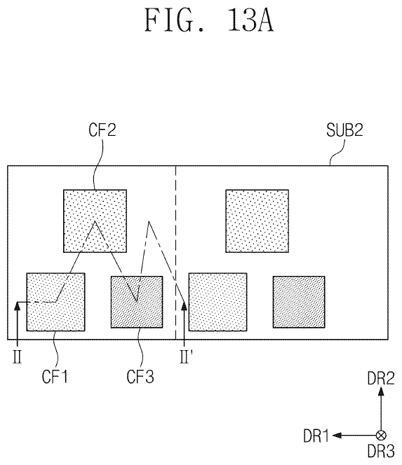

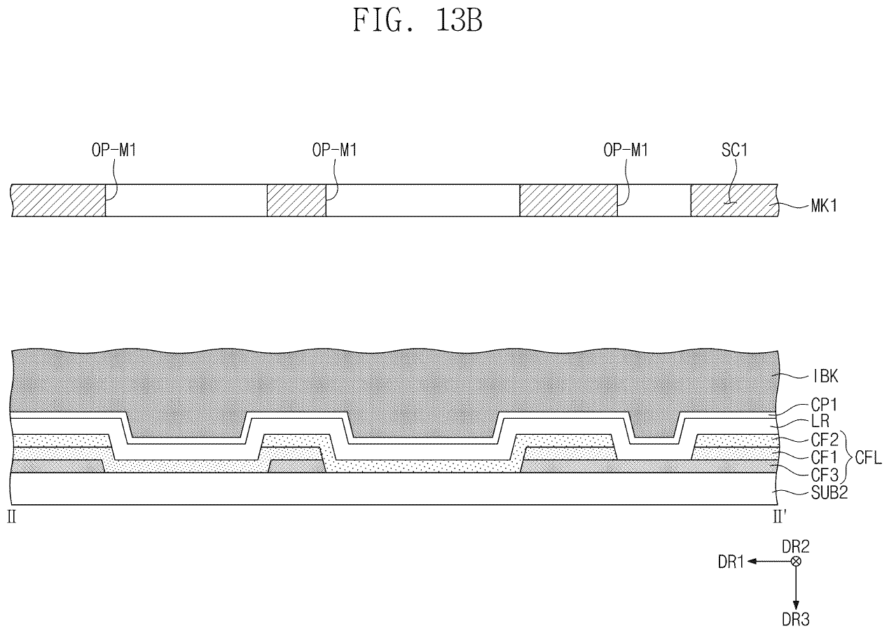

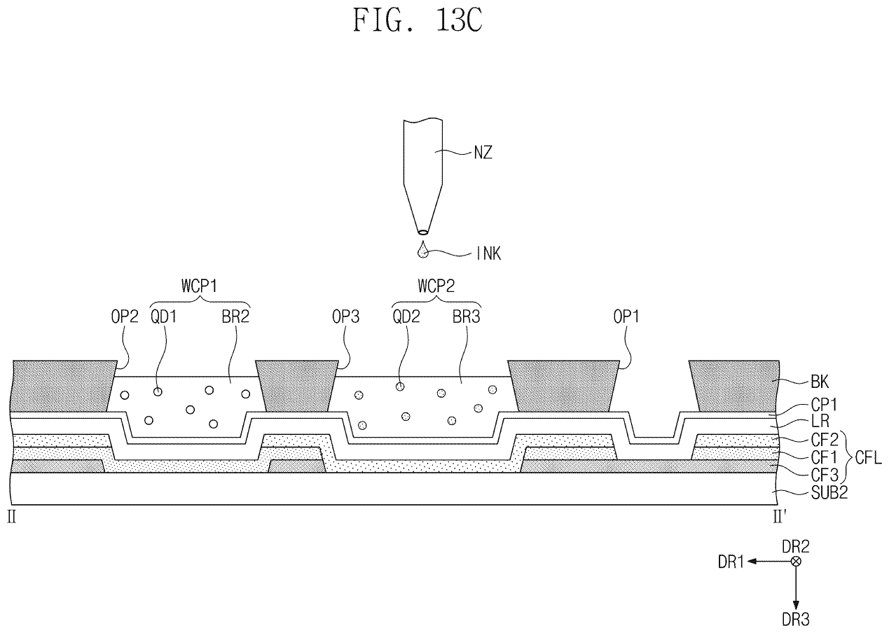

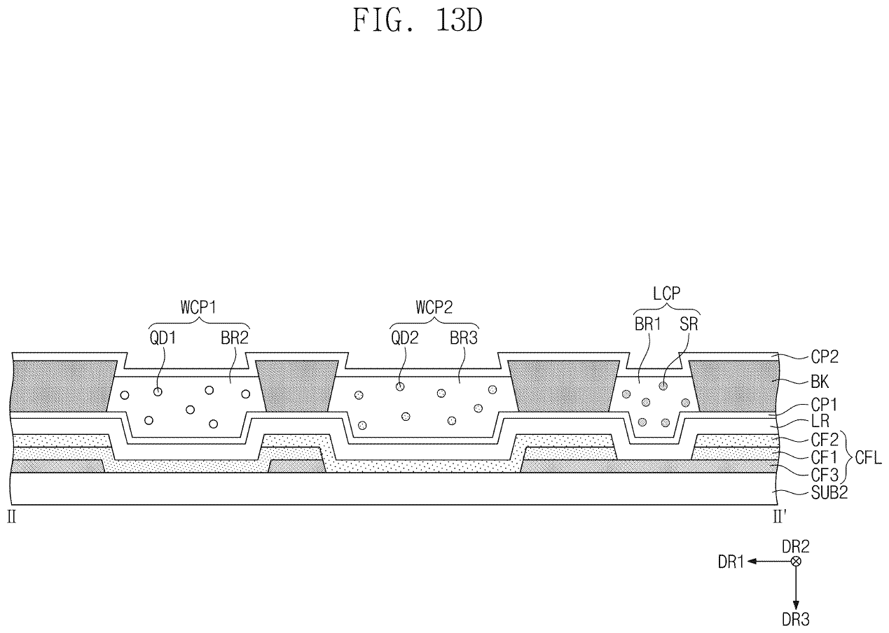

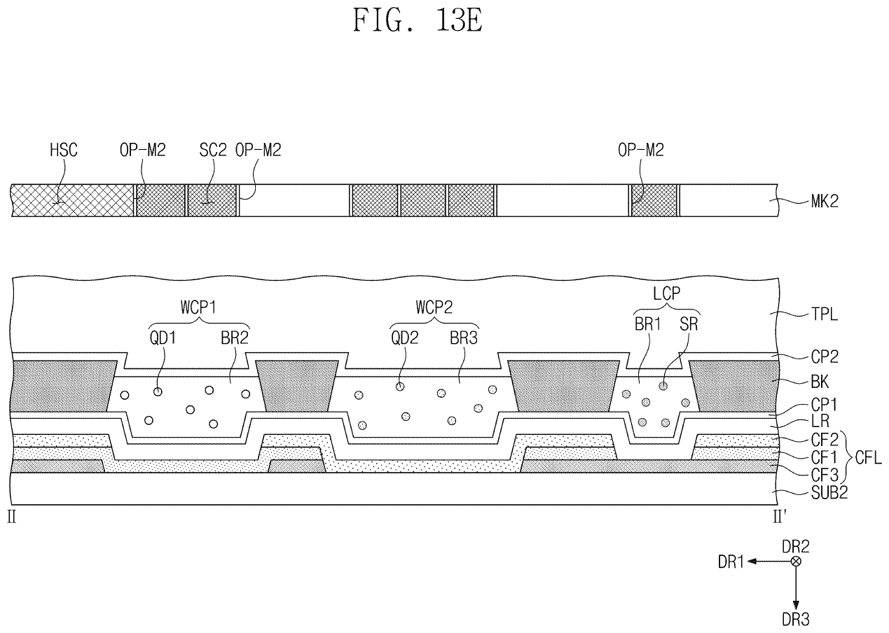

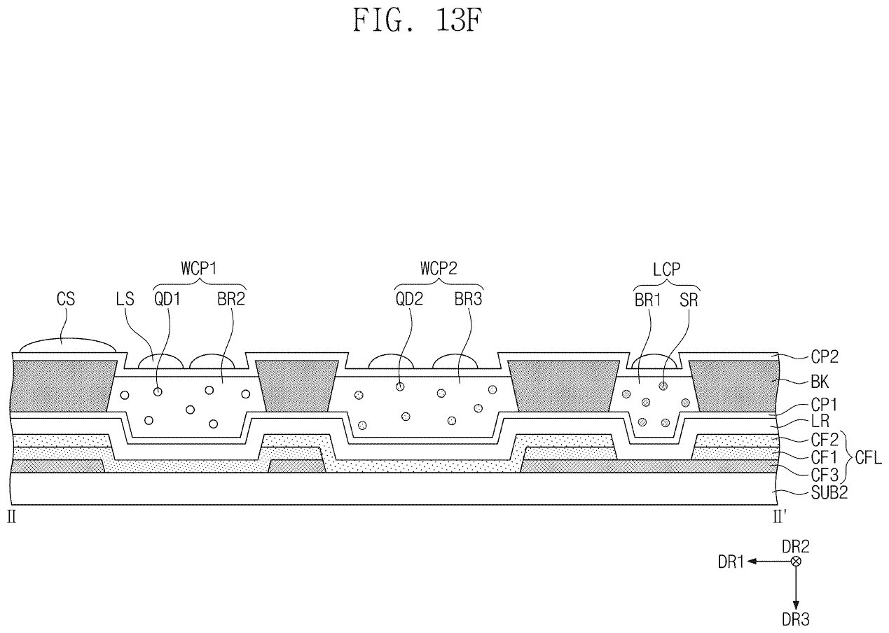

The refractive index of the lenses LS may be the same as the refractive index of the spacer CS. The lenses LS may include the same material as that of the spacer CS. Although not illustrated, the lenses LS and the spacer CS may be formed through the same process at the same time. The forming of the lenses LS and the spacer CS will be described in detail with reference to FIGS. 13E and 13F.

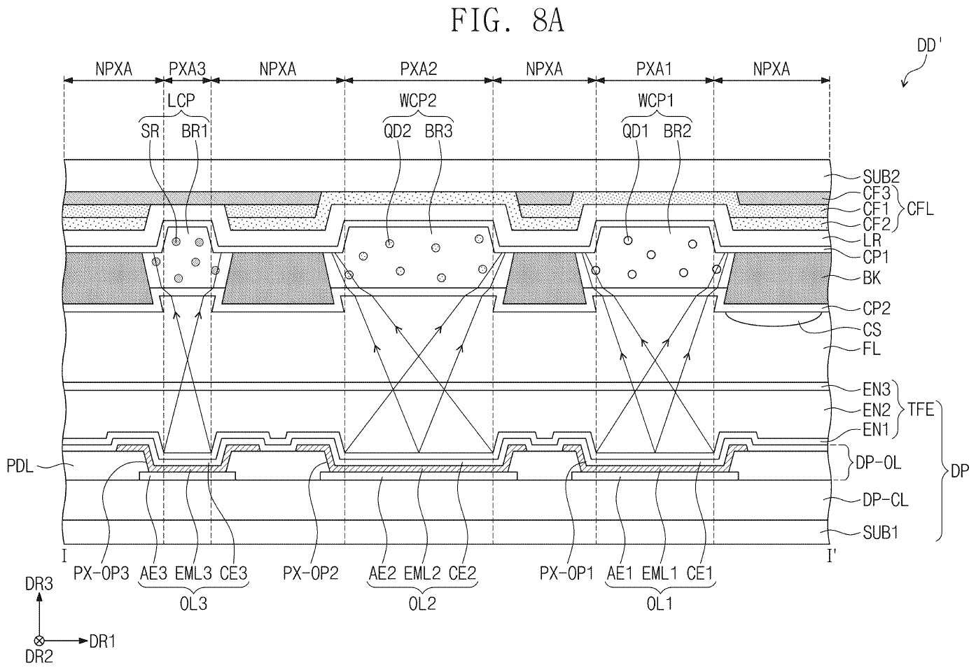

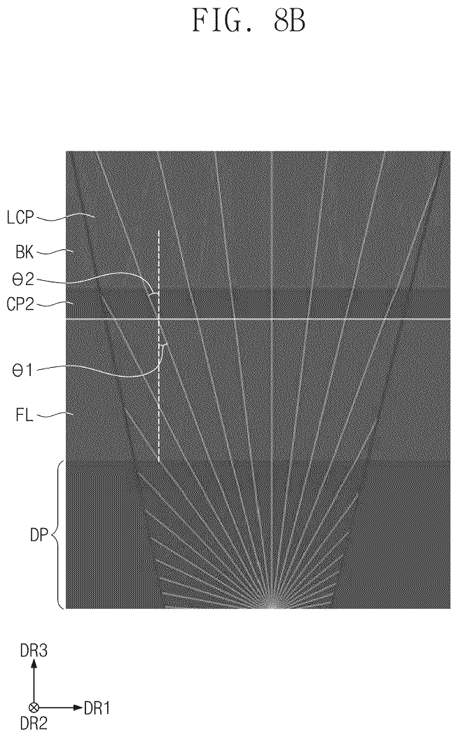

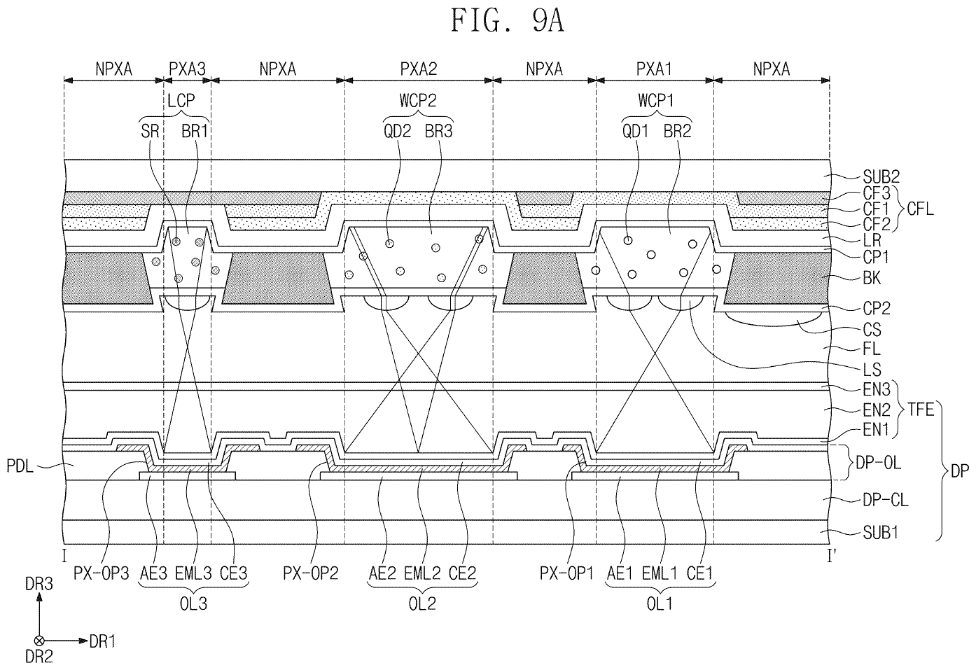

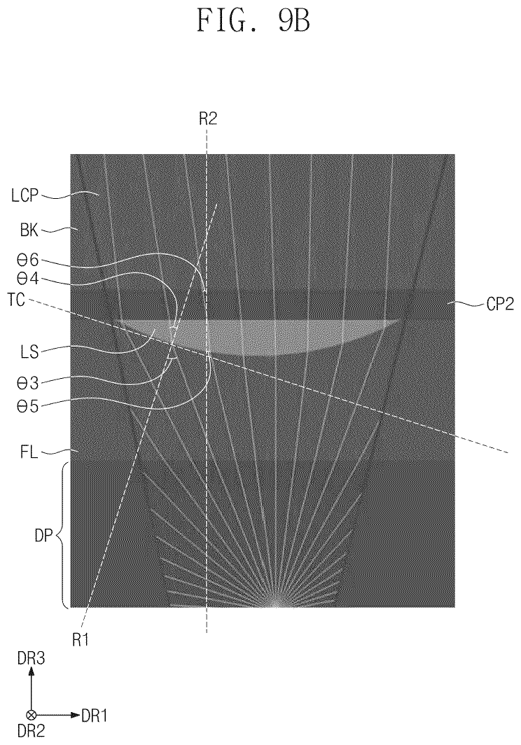

The first light emitted from the light-emitting elements OL1, OL2 and OL3 may pass through the filling member FL and the lenses LS to be incident on the first and second light conversion layers WCP1 and WCP2 and the light transmission layer LCP. The first light passing through the filling member FL may be refracted at an interface between the filling member FL and each of the lenses LS. The refraction of the first light will be described in detail with reference to FIGS. 8A to 9B.

The color filter layer CFL may include a first color filter CF1, a second color filter CF2, and a third color filter CF3. The first to third color filters CF1, CF2 and CF3 may be disposed to correspond to the first to third emission regions PXA1, PXA2 and PXA3, respectively, in a plan view. In an embodiment, the first color filter CF1 may overlap the first emission region PXA1, the second color filter CF2 may overlap the second emission region PXA2, and the third color filter CF3 may overlap the third emission region PXA3, for example.

Each of the first to third color filters CF1, CF2 and CF3 may include a base resin and a pigment or dye dispersed in the base resin. Light having a predetermined wavelength range may pass through each of the first to third color filters CF1, CF2 and CF3 which absorb most of light having a wavelength range other than the predetermined wavelength range.

In an embodiment, the first color filter CF1 may include a red filter, for example. The second color filter CF2 may include a green filter. The third color filter CF3 may include a blue filter. Red light may pass through the red filter which absorbs most of green light and blue light. Green light may pass through the green filter which absorbs most of red light and blue light. Blue light may pass through the blue filter which absorbs most of red light and green light.

The first color filter CF1 may be disposed on the first light conversion layer WCP1. The second light provided from the first light conversion layer WCP1 may pass through the first color filter CF1. In an embodiment, the first light conversion layer WCP1 may convert the first light provided from the first light-emitting element OL1 into red light, and the red light provided from the first light conversion layer WCP1 may pass through the first color filter CF1, for example. The first color filter CF1 may absorb green light and blue light incident toward the first color filter CF1. The first color filter CF1 may absorb light, which is incident toward the first color filter CF1 but is not converted by the first light conversion layer WCP1, thereby preventing the color purity from being decreased in the first emission region PXA1.

The second color filter CF2 may be disposed on the second light conversion layer WCP2, and third light provided from the second light conversion layer WCP2 may pass through the second color filter CF2. In an embodiment, the second light conversion layer WCP2 may convert the first light provided from the second light-emitting element OL2 into green light, and the green light provided from the second light conversion layer WCP2 may pass through the second color filter CF2, for example. The second color filter CF2 may absorb red light and blue light incident toward the second color filter CF2. The second color filter CF2 may absorb light, which is incident toward the second color filter CF2 but is not converted by the second light conversion layer WCP2, thereby preventing the color purity from being decreased in the second emission region PXA2.

The third color filter CF3 may be disposed on the light transmission layer LCP. The first light, which is provided from the third opening OP3 and passes through the light transmission layer LCP, may pass through the third color filter CF3. In an embodiment, blue light may pass through the third color filter CF3 which absorbs green light and red light, thereby preventing the color purity from being decreased in the third emission region PXA3, for example.

External light such as natural light, may be incident toward the display module DM from the outside of the display module DM. The external light may include red light, green light, and blue light. When the display module DM does not include the color filter layer CFL, the external light incident toward the display module DM may be reflected by conductive patterns (e.g., signal lines, electrodes, etc.) inside the display module DM to be provided for a user, and the reflected light may be visible to the user.

The first to third color filters CF1, CF2 and CF3 may prevent the reflection of the external light. In an embodiment, the first color filter CF1 may be a red filter, and absorb light of the external light, which corresponds to green light and blue light, to filter out red light of the external light, for example. In such a principle, the second color filter CF2 may be a green filter, and absorb light of the external light, which corresponds to red light and blue light, to filter out green light of the external light. The third color filter CF3 may be a blue filter, and absorb light of the external light, which corresponds to red light and green light, to filter out blue light of the external light.

At least two color filters of the first to third color filters CF1, CF2 and CF3 may overlap each other within the non-emission region NPXA. In an embodiment, the first to third color filters CF1, CF2 and CF3 may be disposed to overlap each other within the non-emission region NPXA in the third direction DR3, for example. In an embodiment, the first color filter CF1 may be disposed on the third color filter CF3, and the second color filter CF2 may be disposed on the first color filter CF1, for example.

The first to third color filters CF1, CF2 and CF3, which are disposed to overlap each other, may extend onto the bank layers BK to overlap each other. The first to third color filters CF1, CF2 and CF3, which are disposed to overlap each other, may block the light passing through the non-emission region NPXA, thereby preventing a combination of colors between the first to third emission regions PXA1, PXA2 and PXA3.

The upper substrate SUB2 may be disposed on the color filter layer CFL. The upper substrate SUB2 may include a glass substrate, a polymer substrate, or an organic/inorganic composite material substrate. The upper substrate SUB2 may include a front surface and a rear surface, each of which is parallel to the first direction DR1 and the second direction DR2. The rear surface of the upper substrate SUB2 may face the top surface of the lower substrate SUB1. The upper substrate SUB2 may provide a base surface on which components of the light control member LCM are stacked.

FIGS. 8A and 8B are views of a display device according to Comparative Example. FIGS. 9A and 9B are views of an embodiment of a display device according to the inventive concept.

FIGS. 8A and 9A illustrate cross-sectional views of display devices DD′ and DD, respectively, when viewed in the second direction DR2.

FIG. 8B illustrates an enlarged view of a light transmission layer LCP illustrated in FIG. 8A, and FIG. 9B illustrates an enlarged view of a light transmission layer LCP and lenses LS illustrated in FIG. 9A.

FIGS. 8A and 8B and FIGS. 9A and 9B illustrate substantially the same structure except whether the lenses LS are present.

A filling member FL, a second capping layer CP2, first and second light conversion layers WCP1 and WCP2, a light transmission layer LCP, bank layers BK, a low refractive layer LR, a color filter layer CFL, and an upper substrate SUB2 in FIGS. 8A to 9B are the same as/similar to the filling member FL, the second capping layer CP2, the first and second light conversion layers WCP1 and WCP2, the light transmission layer LCP, the bank layers BK, the low refractive layer LR, the color filter layer CFL, and the upper substrate SUB2, respectively, in FIGS. 7 and 8. The lenses LS in FIGS. 9A and 9B are the same as/similar to the lenses LS in FIGS. 6 and 7. Thus, description of the foregoing components will be omitted or provided shortly.

Referring to FIGS. 8A and 8B, first light emitted from a display panel DP may pass through the filling member FL to be incident on the second capping layer CP2. A first angle θ1 may be an angle of incidence of light incident on the second capping layer CP2. A second angle θ2 may be an angle of refraction of light emitted from a boundary between the second capping layer CP2 and the filling member FL. The first angle θ1 may be an angle defined by a virtual line, which is perpendicular to a surface defined by the first direction DR1 and the second direction DR2, and the light incident on the second capping layer CP2. In addition, the second angle θ2 may be an angle defined by the virtual line, which is perpendicular to the surface defined by the first direction DR1 and the second direction DR2, and the light emitted from the boundary between the second capping layer CP2 and the filling member FL.

The first angle θ1 and the second angle θ2 may follow the Snell's law. As the filling member FL has a refractive index higher than a refractive index of the second capping layer CP2, the first light may be refracted. The first angle θ1 may be smaller than the second angle θ2.

A portion of the first light incident on the second capping layer CP2 may pass through the second capping layer CP2 and travel toward the bank layers BK. The light incident on the bank layers BK may be blocked. Accordingly, the light emitted toward the display surface IS illustrated in FIG. 1 may be reduced. Thus, the light-emitting efficiency of the light may be reduced.

Referring to FIGS. 9A and 9B, any first light of the first light of the light incident on the lenses LS will be described for convenience of explanation.

The filling member FL may have a refractive index that is different from a refractive index of the lenses LS. In an embodiment, the refractive index of the filling member FL may be lower than the refractive index of the lenses LS, for example.

The first light emitted from the display panel DP may pass through the filling member FL to be incident on the lenses LS.

A third angle θ3 may be an angle of incidence of light incident toward an interface between the filling member FL and each of the lenses LS. A fourth angle θ4 may be an angle of refraction of light emitted from the interface between the lens LS and the filling member FL. The third angle θ3 may be an angle defined by the light, which is incident on the interface between the lens LS and the filling member FL, and a first reference line R1. The fourth angle θ4 may be an angle defined by the light, which is emitted from the interface between the lens LS and the filling member FL, and the first reference line R1. Hereinafter, the interface may be defined as a boundary between the lens LS and the filling member FL, and the first reference line R1 may be defined as a virtual line that is perpendicular to a tangent TC of the lens LS.

The third angle θ3 and the fourth angle θ4 may follow the Snell's law. As the lens LS has a higher refractive index than that of the filling member FL, the first light may be refracted. The third angle θ3 may be greater than the fourth angle θ4.

The refractive index of the second capping layer CP2 and the refractive index of the lens LS may be different from each other. In an embodiment, the refractive index of the second capping layer CP2 may be lower than the refractive index of the lens LS, for example. The refractive index of the second capping layer CP2 may be lower than the refractive index of the filling member FL.

The first light passing through the lens LS may be incident on the second capping layer CP2. A fifth angle θ5 may be an angle of incidence of the light incident on the second capping layer CP2. A sixth angle θ6 may be an angle of refraction of light emitted from a boundary between the lens LS and the second capping layer CP2 toward the light transmission layer LCP. The fifth angle θ5 may be an angle defined by a second reference line R2 and the light incident on the second capping layer CP2. In addition, the sixth angle θ6 may be an angle defined by the light emitted from the boundary between the lens LS and the second capping layer CP2 toward the light transmission layer LCP. The second reference line R2 may be a virtual line that is perpendicular to a surface defined by the first direction DR1 and the second direction DR2.

The fifth angle θ5 and the sixth angle θ6 may follow the Snell's law. As the lens LS has a higher refractive index than that of the second capping layer CP2, the first light may be refracted. The sixth angle θ6 may be greater than the fifth angle θ5.

As the lenses LS are disposed below the first and second light conversion layers WCP1 and WCP2 and the light transmission layer LCP, first light of the first light emitted from the display panel DP, which is incident toward the bank layers BK, may be refracted when passing through the lenses LS. The first light passing through the lenses LS may be refracted when being incident on the second capping layer CP2. The first light may be refracted multiple times. The first light passing through the second capping layer CP2 may be incident on the first and second light conversion layers WCP1 and WCP2 and the light transmission layer LCP.

As the first light is refracted, first light of the first light, which travels toward the bank layers BK, may be incident on a region adjacent to a center of each of first, second, and third emission regions PXA1, PXA2 and PXA3. The light emitted toward the bank layers BK may decrease. Accordingly, the light emitted toward the display surface IS illustrated in FIG. 1 may increase. Thus, the light-emitting efficiency of the light may be improved.

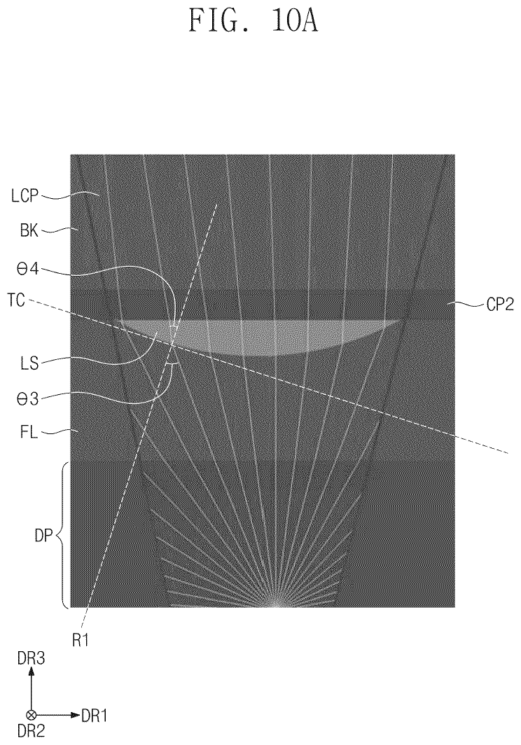

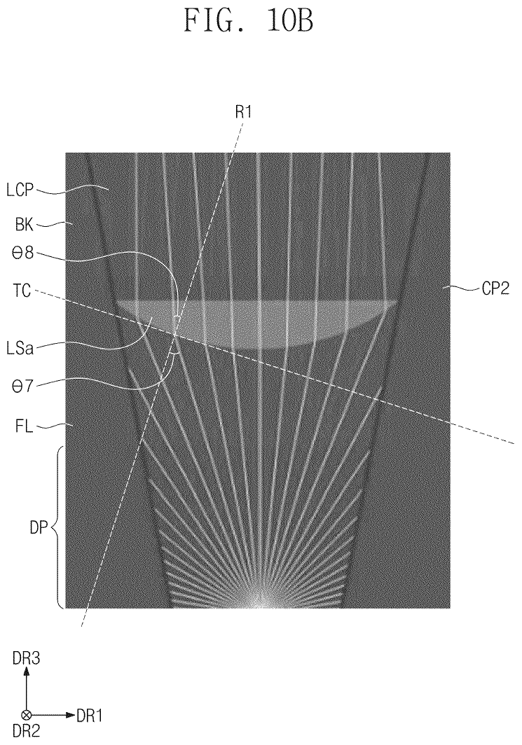

FIGS. 10A and 10B are views for describing refraction of first light according to refractive index change in lenses.

A lens LS and a first lens LSa, each of which is disposed below a light transmission layer LCP, will be illustratively described with reference to FIGS. 10A and 10B, but may be substantially the same as a lens LS and a first lens LSa, respectively, each of which is disposed below each of the first and second light conversion layers WCP1 and WCP2 (refer to FIG. 6).

In an embodiment, a display panel DP, a filling member FL, a second capping layer CP2, bank layers BK, bank layers BK, and a light transmission layer LCP in FIGS. 10A and 10B are the same as/similar to the display panel DP, the filling member FL, the second capping layer CP2, the bank layers BK, the bank layers BK, and the light transmission layer LCP, respectively, in FIGS. 6 and 7, for example. The lens LS, a third angle θ3, and a fourth angle θ4 in FIG. 10A are the same as/similar to the lens LS, the third angle θ3, and the fourth angle θ4, respectively, in FIG. 9B, and a tangent TC and a first reference line R1 in FIGS. 10A and 10B are the same as/similar to the tangent TC and the first reference line R1, respectively, in FIG. 9B. Thus, description of the foregoing components will be omitted or provided shortly.

For convenience of explanation, one lens LS of the plurality of the lenses LS in FIG. 6 will be described, and any first light of the first light incident on the lens LS will be described.

Referring to FIGS. 10A and 10B, the first light may be incident on the lens LS and the first lens LSa. A seventh angle θ7 may be an angle of incidence of light incident on an interface between the first lens LSa and the filling member FL. An eighth angle θ8 may be an angle of refraction of light emitted from the interface between the first lens LSa and the filling member FL. The seventh angle θ7 may be an angle defined by the light, which is incident on the interface between the first lens LSa and the filling member FL, and the first reference line R1. The eighth angle θ8 may be an angle defined by the light, which is emitted from the interface between the first lens LSa and the filling member FL, and the first reference line R1.

The first lens LSa may a refractive index that is higher than a refractive index of the lens LS. In an embodiment, the refractive index of the lens LS may be about 1.57, for example. In an embodiment, the refractive index of the first lens LSa may be about 1.8, for example. A difference between the refractive index of the first lens LSa and the refractive index of the filling member FL may be greater than a difference in refractive index between the lens LS and the filling member FL.

A difference between the seventh angle θ7 and the eighth angle θ8 may be greater than a difference between the third angle θ3 and the fourth angle θ4. That is, a degree to which the first light traveling toward the first lens LSa is refracted may be greater than a degree to which the first light traveling toward the lens LS is refracted. The first light passing through the first lens LSa may pass through the light transmission layer LCP to be adjacent to the third emission region PXA3 (refer to FIG. 6). The first light passing through the first lens LSa may be more adjacent to the center of the third emission region PXA3 (refer to FIG. 6) than the first light passing through the lens LS is.

That is, as the refractive index of the lens LS increases, the first light may be refracted toward a center of the light transmission layer LCP. Accordingly, the light emitted toward the display surface IS illustrated in FIG. 1 may increase. Thus, the light-emitting efficiency of the light may be improved.

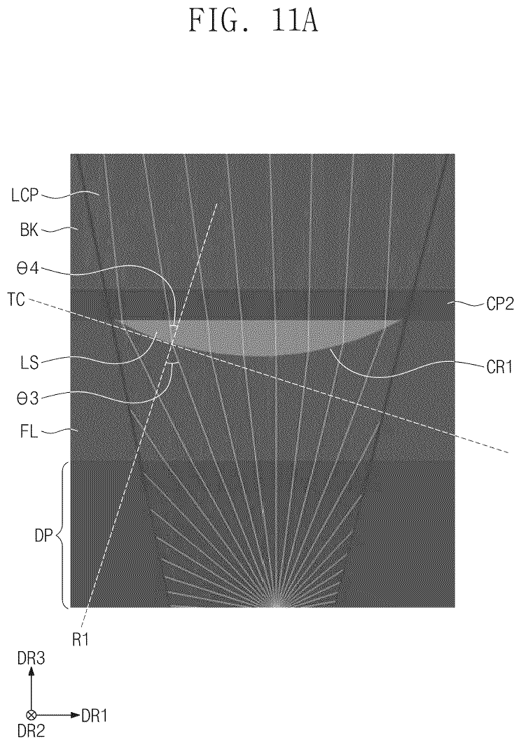

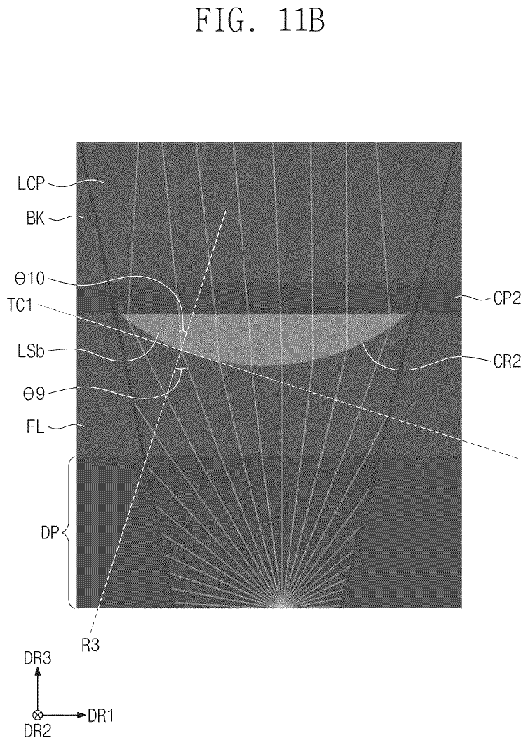

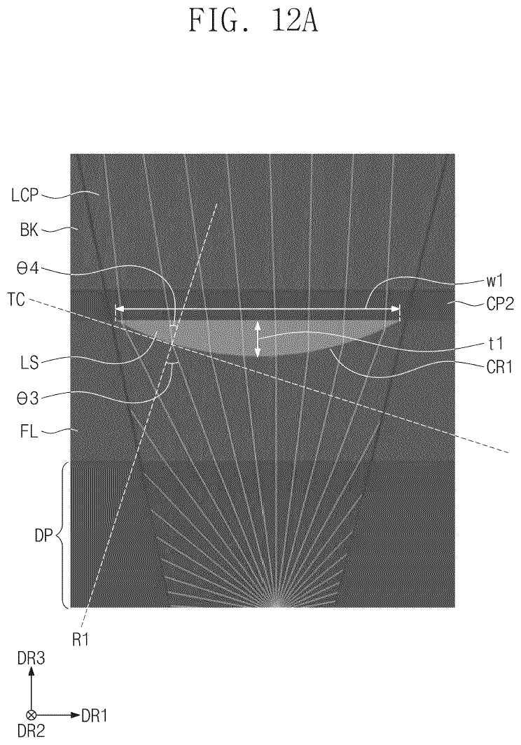

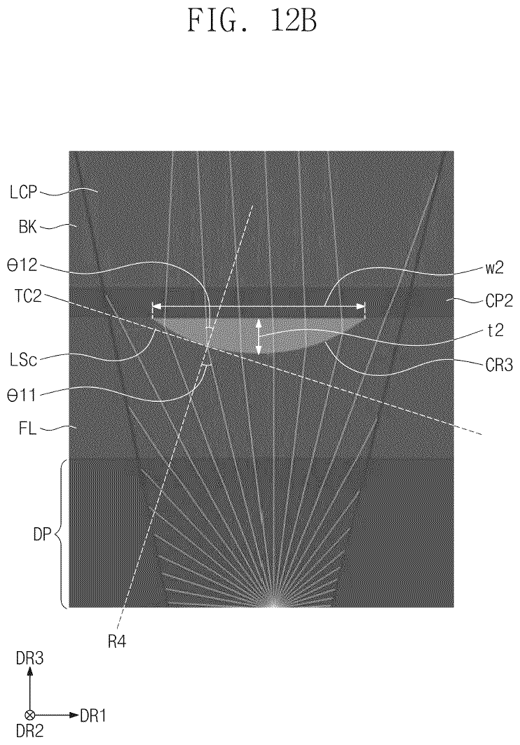

FIGS. 11A and 11B illustrate another embodiment of lenses according to the inventive concept. FIGS. 12A and 12B illustrate another embodiment of lenses according to the inventive concept.

First light incident on a light transmission layer LCP will be illustratively described with reference to FIGS. 11A to 12B, but may be substantially the same as first light incident toward first and second light conversion layers WCP1 and WCP2.

A filling member FL, a second capping layer CP2, the light transmission layer LCP, and bank layers BK in FIGS. 11A to 12B are the same as/similar to the filling member FL, the second capping layer CP2, the light transmission layer LCP, and the bank layers BK, respectively, in FIGS. 8A and 8B. Thus, description of the foregoing components will be omitted or provided shortly.

A lens LS, a third angle θ3, and a fourth angle θ4 in FIGS. 11A and 12A are the same as/similar to the lens LS, the third angle θ3, and the fourth angle θ4, respectively, in FIG. 9B and thus, description thereof will be omitted or provided shortly.

Referring to FIGS. 11A and 11B, a second lens LSb may have a shape that is more convex toward a display panel DP, when compared to the lens LS. The second lens LSb may be more adjacent to the display panel DP than the lens LS is.

Each of the lens LS and the second lens LSb may include a curved surface having a predetermined curvature. The lens LS may have a first curvature CR1 that is smaller than a second curvature CR2 of the second lens LSb.

The first light may be incident on the lens LS and the second lens LSb. Hereinafter, any first light will be described. A ninth angle θ9 may be an angle of incidence of light incident on an interface between the filling member FL and the second lens LSb. A tenth angle θ10 may be an angle of refraction of light emitted from the interface between the filling member FL and the second lens LSb. The ninth angle θ9 may be an angle defined by the light, which is incident on the interface between the filling member FL and the second lens LSb, and a third reference line R3. The tenth angle θ10 may be an angle defined by the light, which is emitted from the interface between the filling member FL and the second lens LSb, and the third reference line R3. Hereinafter, the third reference line R3 may be defined as a virtual line that is perpendicular to a first tangent TC1 of the second lens LSb.

The ninth angle θ9 and the tenth angle θ10 may follow the Snell's law. As the second lens LSb has a higher refractive index than that of the filling member LS, the first light may be refracted. The ninth angle θ9 may be greater than the tenth angle θ10.

A difference between an angle of incidence of the first light incident toward the second lens LSb and a reflection angle thereof may be greater than a difference between an angle of incidence of the first light incident toward the lens LS and a reflection angle thereof. Specifically, a difference between the ninth angle θ9 and the tenth angle θ10 may be greater than the difference between the third angle θ3 and the fourth angle θ4.

The second curvature CR2 of the second lens LSb may be greater than the first curvature CR1 of the lens LS when the second lens LSb is more adjacent to the display panel DP when the lens LS and the second lens LSb have the same width in the first direction DR1. According to such a structure, the refracted degrees of the first light incident on the lens LS and the second lens LSb, respectively, may be different from each other. The first light passing through the second lens LSb may be more refracted than the first light passing through the lens LS.

That is, as a thickness of the lens LS increases, a difference between the angle of incidence and the angle of refraction may increase. Accordingly, much of first light may pass through the light transmission layer LCP and be emitted to a region adjacent to a center of a third emission region PXA3. Thus, the light-emitting efficiency of the light emitted toward the display surface IS may be improved.

Referring to FIGS. 12A and 12B, the lens LS may have a first length w1 that is longer than a second length w2 of a third lens LSc. The lens LS may have a first thickness t1 that is the same as a second thickness t2 of the third lens LSc. The first length w1 and the second length w2 may be defined as lengths of the lens LS and the third lens LSc, respectively, in the first direction DR1. Each of the first and second thicknesses t1 and t2 may be defined as the maximum length from a surface facing the second capping layer CP2 to a curved surface of the lens LS.

As the first and second thicknesses t1 and t2 are the same as each other and the second length w2 is shorter than the first length w1, the third lens LSc may have a third curvature CR3 that is greater than a first curvature CR1 of the lens LS.

The first light may be incident on the lens LS and the third lens LSc. An eleventh angle θ11 may be an angle of incidence of the light incident on the third lens LSc. A twelfth angle θ12 may be an angle of refraction of light emitted from a boundary between the filling member FL and the third lens LSc. The eleventh angle θ11 may be an angle defined by the light incident on the third lens LSc and a fourth reference line R4. The twelfth angle θ12 may be an angle defined by the light, which is emitted from the boundary between the filling member FL and the third lens LSc to the light transmission layer LCP, and the fourth reference line R4. Hereinafter, the fourth reference line R4 may be defined as a virtual line that is perpendicular to a second tangent TC2 of the third lens LSc.

The eleventh angle θ11 and the twelfth angle θ12 may follow the Snell's law. As the third lens LSc has a higher refractive index than that of the filling member FL, the first light may be refracted. The eleventh angle θ11 may be greater than the twelfth angle θ12.

A difference between an angle of incidence of the first light incident toward the third lens LSc and a reflection angle thereof may be greater than a difference between an angle of incidence of the first light incident toward the lens LS and a reflection angle thereof. Specifically, a difference between the eleventh angle θ11 and the twelfth angle θ12 may be greater than the difference between the third angle θ3 and the fourth angle θ4.

When the first thickness t1 of the lens LS and the second thickness t2 of the third lens LSc are the same as each other, the second length w2 of the third lens LSc is shorter than the first length w1 of the lens LS and thus, the third curvature CR3 may be greater than the first curvature CR1. According to such a structure, the refracted degrees of the first light incident on the lens LS and the third lens LSc, respectively, may be different from each other. The first light passing through the third lens LSc may be more refracted than the first light passing through the lens LS. That is, when the lens LS has the same thickness, the shorter the length in the first direction DR1 is, the greater the difference between the angle of incidence and the reflection angle may be. Accordingly, much of first light may pass through the light transmission layer LCP and be emitted to a region adjacent to a center of the light transmission layer LCP. Thus, the light-emitting efficiency of the light emitted toward the display surface IS may be improved.

FIGS. 13A to 13F are views for describing a process for forming the light control layer illustrated in FIGS. 6 and 7.

FIG. 13A illustrates a plan view of a portion of the light control layer LCL illustrated in FIG. 7.

FIGS. 13B to 13F illustrate cross-sectional views taken along line II-II′ illustrated in FIG. 13A.

For convenience of explanation, FIGS. 13A to 13F illustrate the light control layer LCL illustrated in FIG. 6 to be symmetric in the third direction DR3.

A color filter layer CFL, a low refractive layer LR, an upper substrate SUB2, and a first capping layer CP1 in FIGS. 13A to 13F are the same as/similar to the color filter layer CFL, the low refractive layer LR, the upper substrate SUB2, and the first capping layer CP1, respectively, in FIGS. 6 and 7. Thus, description of the foregoing components will be omitted or provided shortly.

Referring to FIGS. 6 and 13A, the color filter layer CFL may be disposed on the upper substrate SUB2. The first capping layer CP1 and the low refractive layer LR may be disposed in sequence on the color filter layer CFL.

Referring to FIG. 13B, a preliminary bank layer IBK may be provided on the color filter layer CFL. The preliminary bank layer IBK may be provided on a top surface of the first capping layer CP1. The preliminary bank layer IBK may cover the first capping layer CP1. The preliminary bank layer IBK may include a black pigment and a water-repellent material.

A first mask MK1 may be disposed above the preliminary bank layer IBK. The first mask MK1 may be a photomask for shielding light. The first mask MK1 may include a plurality of first shielding parts SC1. The first shielding parts SC1 may overlap the non-emission region NPXA in FIG. 6.

Each of first mask openings OP-M1 may be defined between the first shielding parts SC1 adjacent to each other in the first direction DR1. Each of the first mask openings OP-M1 may correspond to a corresponding emission region PXA1, PXA2 or PXA3 among the emission regions PXA1, PXA2 and PXA3 in FIG. 6.

Although not illustrated, a light source may be disposed on the first mask MK1. An exposure process may be performed by light emitted from the light source. The light may pass through the first mask openings OP-M1 and be emitted onto the preliminary bank layer IBK. The molecular composition or components of the preliminary bank layer IBK, which is irradiated with the light in the preliminary bank layer IBK, may change.

Although not illustrated, an etching process may be carried out after the exposure process is performed. The etching process may be chemical or physical etching. The chemical etching may be a process using a developing solution. The physical etching may be dry or wet etching. When the etching process is completed, the bank layers BK in FIG. 6 may be formed.

Referring to FIGS. 6 and 13C, a nozzle NZ may be provided above the first to third openings OP1 to OP3 that overlap the emission regions PXA1, PXA2 and PXA3, respectively. The nozzle NZ may eject an ink INK into each of the first to third openings OP1 to OP3.

The inks INK ejected into the first to third openings OP1 to OP3 may be different from each other. Specifically, an ink including the first base resin BR1 and the scatterers SR in FIG. 6 may be ejected into the first opening OP1. An ink including first quantum dots QD1 and a second base resin BR2 may be ejected into the second opening OP2. An ink including second quantum dots QD2 and a third base resin BR3 may be ejected into the third opening OP3.

As the nozzle NZ ejects the ink INK, the first light conversion layer WCP1, the second light conversion layer WCP2, and the light transmission layer LCP may be formed.

Referring to FIG. 13D, a display device manufacturing method in an embodiment may further include forming the second capping layer CP2 (refer to FIG. 6) on the light control layer LCL.

Referring to FIGS. 6, 13E and 13F, a transparent material TPL may be disposed on the second capping layer CP2. The transparent material TPL may cover the second capping layer CP2.

A second mask MK2 may be disposed on the transparent material TPL. The second mask MK2 may include second shielding parts SC2 and a semi-shielding part HSC. The second shielding parts SC2 may be disposed on a region overlapping the lenses LS in FIG. 6. The semi-shielding part HSC may be disposed on a region overlapping the spacer CS in FIG. 6.

A plurality of second mask openings OP-M2 may be defined in the second mask MK2. The second mask openings OP-M2 may overlap between the lenses LS that are adjacent to each other in the first direction DR1. The second mask openings OP-M2 may overlap the bank layers BK, respectively. The semi-shielding part HSC may be a portion of which light transmittance is higher than the second shielding parts SC2 and lower than the second mask openings OP-M2.

Although not illustrated, a light source may be disposed on the second mask MK2. An exposure process may be performed by light emitted from the light source. The light may pass through the second mask openings OP-M2 and the semi-shielding part HSC and be emitted onto the transparent material TPL. The molecular composition or components of the transparent material TPL, which is irradiated with the light in the transparent material TPL, may change.

As the second mask MK2 includes the second shielding parts SC2 and the semi-shielding part HSC, the spacer CS and the lenses LS may be formed at the same time. The spacer CS and the lenses LS may be formed in the same layer. As the second mask MK2 includes the second shielding parts SC2 and the semi-shielding part HSC, the spacer CS and the lenses LS may be different in thickness.

Although not illustrated, the display device manufacturing method in an embodiment of the inventive concept may include disposing the light control layer LCL on the display panel DP in FIG. 6 after the spacer CS and the lenses LS are formed. The filling member FL may be disposed between the light control layer LCL and the display panel DP.

The lenses LS may have a refractive index that is higher than that of each of the filling member FL and the second capping layer CP2. The spacer CS and the lenses LS may have the same refractive index. Thus, the light emitted from the display panel DP may be refracted at a boundary between the filling member FL and each of the lenses LS.

Although the embodiments of the invention have been described, it is understood that the invention should not be limited to these embodiments but various changes and modifications may be made by one ordinary skilled in the art within the spirit and scope of the invention as hereinafter claimed. Therefore, the technical scope of the inventive concept is not limited to the contents described in the detailed description of the specification, but should be determined by the claims.

What is claimed is:

1. A display device comprising:
a display panel;
a first light conversion layer, a second light conversion layer, and a light transmission layer, which are disposed on the display panel and spaced apart from each other;
bank layers, each of which is disposed on the display panel and which are disposed between the first light conversion layer and the second light conversion layer and between the light transmission layer and each of the first and second light conversion layers;
a spacer disposed below a bank layer of the bank layers and facing the display panel; and
a plurality of lenses disposed below the first light conversion layer, the second light conversion layer, and the light transmission layer, and facing the display panel,
wherein the spacer and the plurality of lenses are disposed in a same layer.

2. The display device of claim 1, wherein the plurality of lenses is arranged in a matrix shape when viewed in a plan view.

3. The display device of claim 2, wherein each of the plurality of lenses has a circular shape when viewed on the plan view.

4. The display device of claim 1, further comprising a filling member disposed between the spacer and the display panel,
wherein light emitted from the display panel passes through the filling member and each of the plurality of lenses, and is incident on each of the first and second light conversion layers and the light transmission layer.

5. The display device of claim 4, wherein a refractive index of the plurality of lenses is higher than a refractive index of the filling member.

6. The display device of claim 5, wherein the light emitted from the display panel is refracted at a boundary between the filling member and each of the plurality of lenses, and the light is incident on a region adjacent to a center of each of the first light conversion layer, the second light conversion layer, and the light transmission layer.

7. The display device of claim 5, wherein, as a difference between the refractive index of the filling member and the refractive index of the plurality of lenses increases, a difference between an angle of incidence of the light, which travels toward an interface between each of the plurality of lenses and the filling member, and an angle of refraction of the light emitted from the interface increases.

8. The display device of claim 5, wherein, as a thickness of each of the plurality of lenses increases, a difference between an angle of incidence of the light, which travels toward an interface between each of the plurality of lenses and the filling member, and an angle of refraction of the light emitted from the interface increases.

9. The display device of claim 5, wherein, as a width of each of the plurality of lenses decreases, a difference between an angle of incidence of the light, which travels toward an interface between each of the plurality of lenses and the filling member, and an angle of refraction of the light emitted from the interface increases.

10. The display device of claim 1, wherein the display panel comprises:
emission regions which overlap the first light conversion layer, the second light conversion layer and the light transmission layer, respectively; and
non-emission regions, each of which is disposed between the emission regions adjacent to each other,
wherein the spacer overlaps the non-emission regions, and the plurality of lenses overlap the emission regions.

11. The display device of claim 1, wherein the spacer is more adjacent to the display panel than the plurality of lenses is.

12. The display device of claim 1, wherein the spacer and the plurality of lenses comprise a same material as each other.

13. The display device of claim 1, further comprising:
a first color filter disposed on the first light conversion layer;
a second color filter disposed on the second light conversion layer; and
a third color filter disposed on the light transmission layer.

14. The display device of claim 13, wherein the first, second, and third color filters extend onto the bank layer and overlap each other.

15. A display device manufacturing method comprising:
forming a bank layer on a substrate;
providing light conversion layers and a light transmission layer in openings defined in the bank layer;
forming a spacer on the bank layer;
forming a plurality of lenses on the light conversion layers and the light transmission layer; and
disposing the light conversion layers and the light transmission layer on a display panel so as to face the display panel,
wherein the spacer and the plurality of lenses are formed at a same time.

16. The display device manufacturing method of claim 15, wherein the spacer and the plurality of lenses are disposed in a same layer.

17. The display device manufacturing method of claim 15, wherein the plurality of lenses is formed in a matrix shape on the light conversion layers and the light transmission layer when viewed in a plan view.

18. The display device manufacturing method of claim 17, wherein each of the plurality of lenses has a circular shape when viewed on the plan view.

19. The display device manufacturing method of claim 15, further comprising providing a filling member between the display panel and the light transmission layer and between the display panel and each of the light conversion layers,
wherein a refractive index of the plurality of lenses is higher than a refractive index of the filling member.

20. The display device manufacturing method of claim 15, wherein the spacer and the plurality of lenses comprises a same material as each other.
